(19) United States
(12) Patent Application Publication
(10) Pub. No.: US 2025/0261396 A1
(43) Pub. Date: Aug. 14, 2025

(54) SEMICONDUCTOR DEVICE

(71) Applicant: SAMSUNG ELECTRONICS CO., LTD., Suwon-si (KR)

(72) Inventors: Jaeho Jeon, Suwon-si (KR); Donghoon Hwang, Suwon-si (KR); Byungho Moon, Suwon-si (KR); Choonghwan Kim, Suwon-si (KR)

(21) Appl. No.: 19/013,997

(22) Filed: Jan. 8, 2025

(30) Foreign Application Priority Data
Feb. 8, 2024 (KR) 10-2024-0019835

(51) Int. Cl. H10D 30/00; H10D 30/01; H10D 30/43; H10D 30/67; H10D 62/10; H10D 84/01; H10D 84/83

(52) U.S. Cl. CPC H10D 30/502; H10D 30/014; H10D 30/0191; H10D 30/43; H10D 30/6735; H10D 62/121; H10D 84/0153; H10D 84/832

(57) ABSTRACT

A semiconductor device includes a substrate including a fin-type active area and a device separation layer configured to cover both sidewalls of the fin-type active area, a pair of nanosheet stacks each including a lower nanosheet stack arranged on the fin-type active area and an upper nanosheet stack arranged on the lower nanosheet stack, an intermediate insulating layer arranged between the lower nanosheet stack and the upper nanosheet stack, a nanosheet separation wall arranged between each of the pair of nanosheet stacks and extending in a first horizontal direction, and a pair of gate lines extending on the pair of nanosheet stacks in a second horizontal direction, wherein the nanosheet separation wall separates respective lower nanosheet stacks in the pair of nanosheet stacks from each other in the second horizontal direction.

### CROSS-REFERENCE TO RELATED APPLICATION

This application claims priority under 35 U.S.C. § 119 to Korean Patent Application No. 10-2024-0019835, filed on Feb. 8, 2024, in the Korean Intellectual Property office, the entirety of which is incorporated by reference herein.

### BACKGROUND

Due to the development of electronic technology, the demand for high integration of semiconductor devices is increasing and downscaling of the semiconductor devices is proceeding. Down-scaling of the semiconductor devices may cause a short channel effect of transistors, which reduces the reliability of integrated circuit devices. To reduce the short channel effect, a semiconductor device of a multi-gate structure such as a nanosheet-type transistor has been proposed.

### SUMMARY

Some aspects of this disclosure provide semiconductor devices with improved operation characteristics.

According to some implementations of the present disclosure, there is provided a semiconductor device including a substrate including a fin-type active area and a device separation layer configured to cover both sidewalls of the fin-type active area, a pair of nanosheet stacks each including a lower nanosheet stack arranged on the fin-type active area and an upper nanosheet stack arranged on the lower nanosheet stack, an intermediate insulating layer arranged between the lower nanosheet stack and the upper nanosheet stack, a nanosheet separation wall arranged between each of the pair of nanosheet stacks and extending in a first horizontal direction, and a pair of gate lines extending on the pair of nanosheet stacks in a second horizontal direction, wherein the nanosheet separation wall separates respective lower nanosheet stacks in the pair of nanosheet stacks from each other in the second horizontal direction.

According to some implementations of the present disclosure, there is provided a semiconductor device including a substrate including a fin-type active area and a device separation layer configured to cover both sidewalls of the fin-type active area, a pair of nanosheet stacks each including a lower nanosheet stack arranged on the fin-type active area and an upper nanosheet stack arranged on the lower nanosheet stack, an intermediate insulating layer arranged between the lower nanosheet stack and the upper nanosheet stack, a nanosheet separation wall arranged between the pair of nanosheet stacks and extending in a first horizontal direction, a gate separation spacer arranged on one sidewall relatively distant in a second horizontal direction from the nanosheet separation wall, among both sidewalls of each of the upper nanosheet stacks respectively included in the pair of nanosheet stacks, and a pair of gate lines extending on the pair of nanosheet stacks in the second horizontal direction, wherein the nanosheet separation wall separates lower nanosheet stacks each included in the pair of nanosheet stacks from each other in the second horizontal direction.

According to some implementations of the present disclosure, there is provided a semiconductor device including a substrate including a fin-type active area and a device separation layer configured to cover both sidewalls of the fin-type active area and arranged in a device separation trench, a pair of nanosheet stacks each including a lower nanosheet stack arranged on the fin-type active area and an upper nanosheet stack arranged on the lower nanosheet stack, an intermediate insulating layer arranged between the lower nanosheet stack and the upper nanosheet stack, a nanosheet separation wall arranged between the one pair of nanosheet stacks and extending in a first horizontal direction, a residual insulating material arranged on lower end edges of both sidewalls of the device separation trench adjacent to the pair of nanosheet stacks in a second horizontal direction, a gate separation spacer arranged on one sidewall relatively distant in the second horizontal direction from the nanosheet separation wall, among both sidewalls of each of the upper nanosheet stacks respectively included in the pair of nanosheet stacks, a pair of gate lines extending on the pair of nanosheet stacks in the second horizontal direction, and including a first metal layer, a second metal layer, and a third metal layer, and a gate cut structure including a first gate cut structure configured to separate the upper nanosheet stacks each included in the pair of nano sheet stacks from each other in the second horizontal direction, and a second gate cut structure configured to separate another pair of nanosheet stacks adjacent to the pair of nanosheet stacks from the pair of nanosheet stacks in the second horizontal direction, wherein the nanosheet separation wall separates the lower nanosheet stacks respectively included in the pair of nanosheet stacks from each other in the second horizontal direction, and the third metal layer includes a lower gate metal layer and an upper gate metal layer, which are apart from each other by the gate separation spacer.

### BRIEF DESCRIPTION OF THE DRAWINGS

The foregoing and other implementations will be more clearly understood from the following detailed description taken in conjunction with the accompanying drawings in which:

FIG. 1 is a schematic top view of an example of a semiconductor device according to some implementations;

FIG. 2A is a cross-sectional view of the semiconductor device taken along line X1-X1′ in FIG. 1;

FIG. 2B is a cross-sectional view of the semiconductor device taken along line Y1-Y1′ in FIG. 1;

FIG. 3 is a cross-sectional view of an example of a semiconductor device according to some implementations;

FIG. 4 is a cross-sectional view of an example of a semiconductor device according to some implementations; and

FIGS. 5A-26D are cross-sectional views illustrating an example of a manufacturing method of a semiconductor device, according to some implementations.

### DETAILED DESCRIPTION

Hereinafter, examples are described in detail with reference to the accompanying drawings. Identical reference numerals are used for the same constituent elements in the drawings, and duplicate descriptions thereof are omitted.

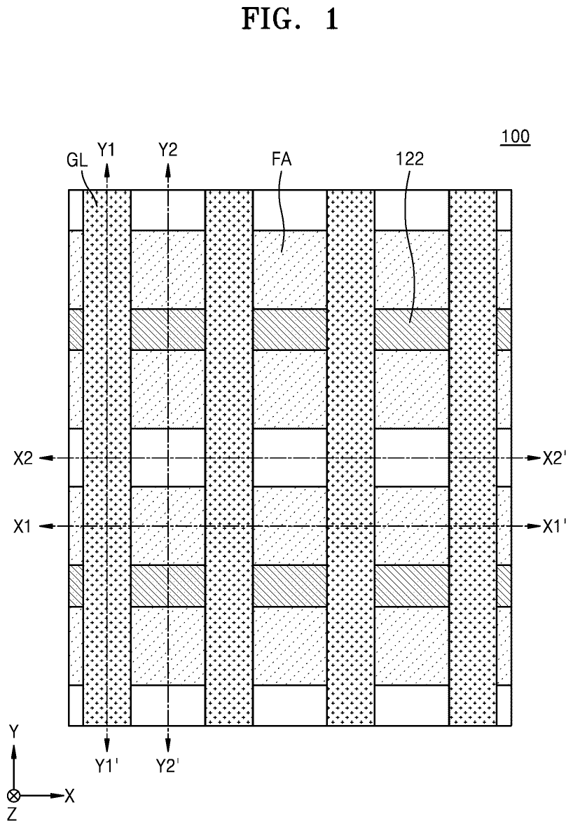

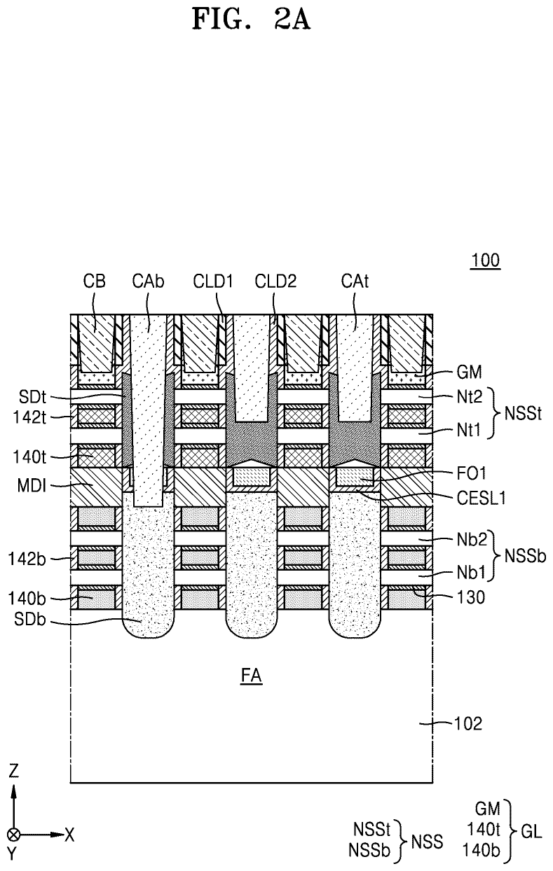

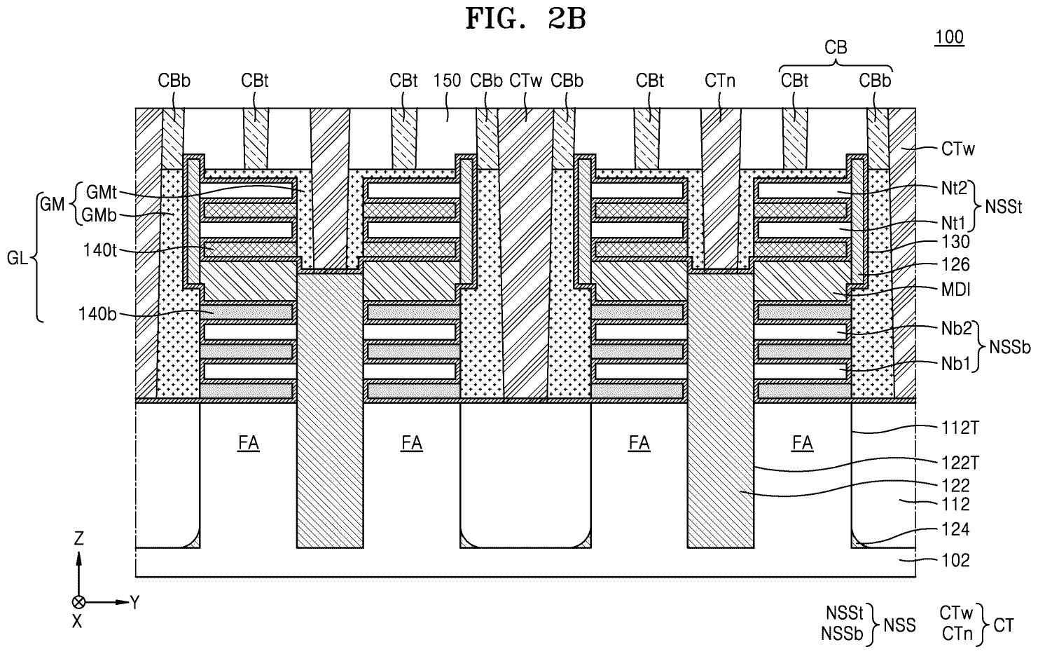

FIG. 1 is a schematic top view of a semiconductor device 100 according to some implementations. FIG. 2A is a cross-sectional view of the semiconductor device 100 taken along line X1-X1′ in FIG. 1. FIG. 2B is a cross-sectional view of the semiconductor device 100 taken along line Y1-Y1′ in FIG. 1.

Referring to FIGS. 1, 2A, and 2B, the semiconductor device 100 may include a substrate 102 having a fin-type active area FA, a plurality of gate lines GL, a plurality of nanosheet stacks NSS, and a plurality of nanosheet separation walls 122.

The semiconductor device 100 may include a plurality of logic cells. The plurality of logic cells may each include a plurality of circuit elements, such as a transistor and a register, and may be variously configured. The logic cell may constitute, for example, an AND gate, a NAND gate, an OR gate, a NOR gate, an exclusive OR (XOR) gate, an exclusive NOR (XNOR) gate, an inverter (INV), an adder (ADD), a buffer (BUF), a delay (DLY), a filter (FIL), a multiplexer (MXT/MXIT), an OR/AND INV (OAI), an AND/OR (AO) INV (AOI), a D flip-flop, a reset flip-flop, a master-slave flip-flop, a latch, and/or the like, and may constitute a standard cell performing a logic function.

The substrate 102 may include a Group IV semiconductor, such as silicon (Si) and germanium (Ge), a Group IV-IV compound semiconductor, such as silicon-germanium (SiGe) and silicon carbide (SiC), or a Group III-V semiconductor, such as gallium arsenide (GaAs), indium arsenide (InAs), and indium phosphide (InP). The terms “SiGe”, “SiC”, “GaAs”, “InAs”, and “InP” and the like used herein refer to materials including the elements included in each term, but do not represent a stoichiometric relationship. The substrate 102 may include a conductive area, for example, a well doped with impurities, or a structure doped with impurities.

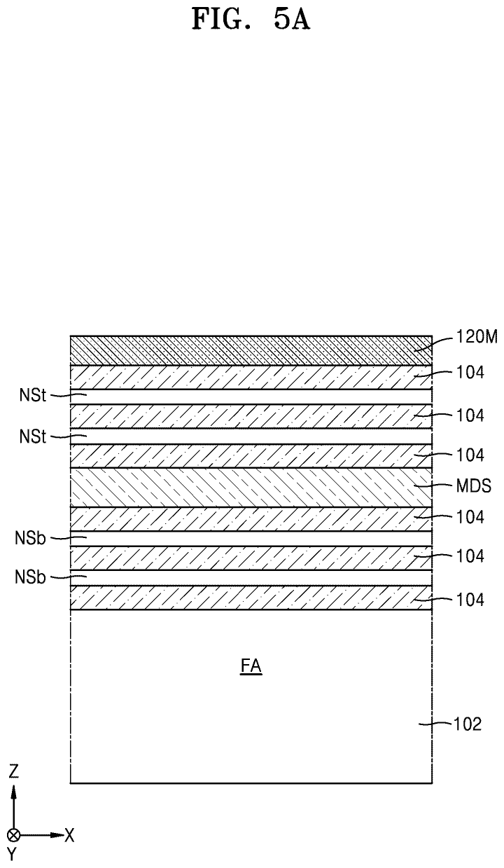

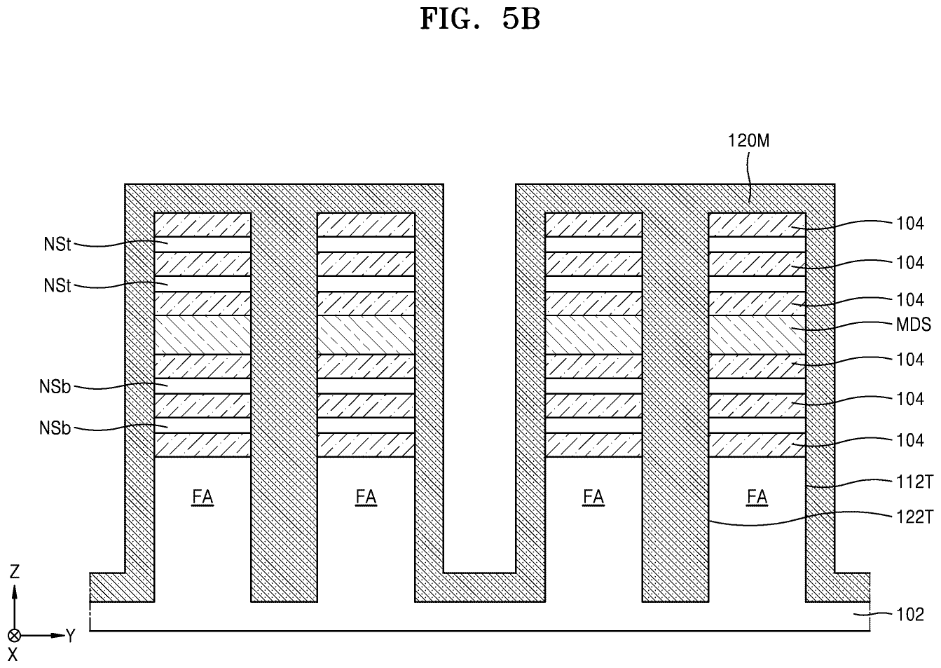

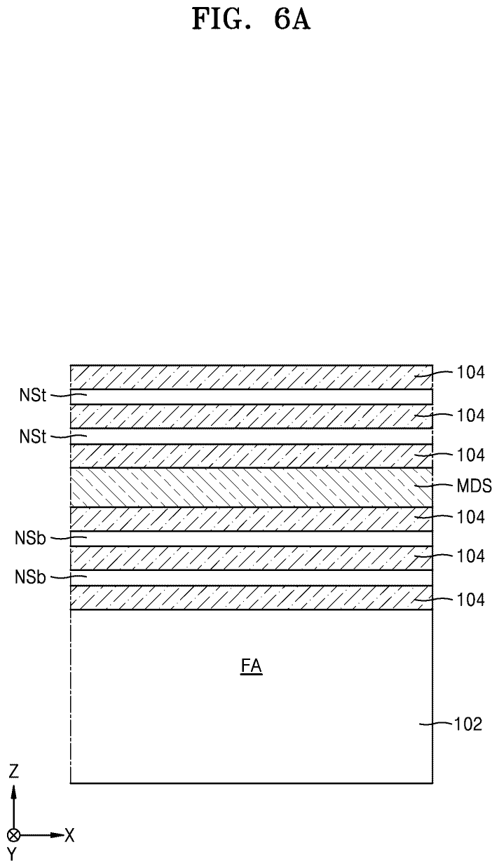

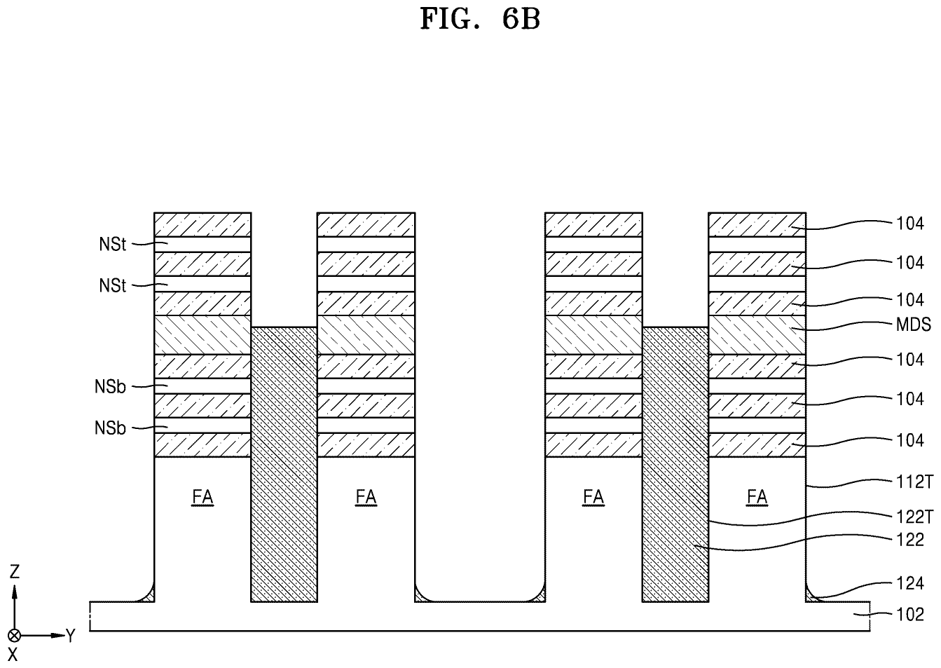

A device separation layer 112 may be formed in a device separation layer trench 112T formed in the substrate 102. The device separation layer 112 may cover both sidewalls of the fin-type active area FA. The device separation layer 112 may include, for example, an oxide layer, a nitride layer, or a combination thereof. A residual insulating material 124 may be arranged at a lower edge of both sidewalls of the device separation layer trench 112T adjacent to the nanosheet stack NSS in a second horizontal direction (Y direction). The residual insulating material 124 may include a material which has not been removed and remains during a forming process of the nanosheet separation wall 122 to be described below with reference to FIGS. 5A, 5B, 6A, and 6B. Accordingly, the residual insulating material 124 may substantially include the same material as the nanosheet separation wall 122.

The fin-type active area FA may protrude from an upper surface of the substrate 102 in a vertical direction (Z direction). The fin-type active areas FA may extend in parallel with each other in a first horizontal direction (X direction).

The plurality of gate lines GL may extend in parallel with each other on the fin-type active area FA in the second horizontal direction (Y direction). The plurality of nanosheet stacks NSS may be arranged in areas, where the fin-type active area FA and the plurality of gate lines GL cross each other, on the fin-type active area FA. The plurality of nanosheet stacks NSS may be arranged to form rows and columns in the first horizontal direction (X direction) and the second horizontal direction (Y direction).

Each of the plurality of nanosheet stacks NSS may include a lower nanosheet stack NSSb arranged on the fin-type active area FA, and an upper nanosheet stack NSSt arranged on the lower nanosheet stack NSSb. The lower nanosheet stack NSSb may include a first nanosheet Nb1 and a second nanosheet Nb2, which are sequentially stacked on the fin-type active area FA, and the upper nanosheet stack NSSt may include a third nanosheet Nt1 and a fourth nanosheet Nt2, which are sequentially stacked on the lower nanosheet stack NSSb. The first nanosheet Nb1, the second nanosheet Nb2, the third nanosheet Nt1, and the fourth nanosheet Nt2 may each include a Group IV semiconductor, such as Si and Ge, a Group IV-IV compound semiconductor, such as SiGe and SiC, or a Group III-V compound semiconductor, such as GaAs, InAs, and InP. Each of the first nanosheet Nb1, the second nanosheet Nb2, the third nanosheet Nt1, and the fourth nanosheet Nt2 may have a channel area (not illustrated). In some implementations, the first nanosheet Nb1, the second nanosheet Nb2, the third nanosheet Nt1, and the fourth nanosheet Nt2 have substantially the same thickness in the vertical direction (Z direction). In some implementations, at least some of the first nanosheet Nb1, the second nanosheet Nb2, the third nanosheet Nt1, and the fourth nanosheet Nt2 have different thicknesses in the vertical direction (Z direction).

In FIGS. 2A and 2B, each of the lower nanosheet stack NSSb and the upper nanosheet stack NSSt is illustrated to include two nanosheets, but the number of nanosheets is not limited thereto. For example, each of the lower nanosheet stack NSSb and the upper nanosheet stack NSSt may include one, three, or more than three nanosheets.

In some implementations, each of the first nanosheet Nb1, the second nanosheet Nb2, the third nanosheet Nt1, and the fourth nanosheet Nt2, which are included in each of the lower nanosheet stack NSSb and the upper nanosheet stack NSSt, have the same size in the first horizontal direction (X direction). In some implementations, at least some of the first nanosheet Nb1, the second nanosheet Nb2, the third nanosheet Nt1, and the fourth nanosheet Nt2, which are included in each of the lower nanosheet stack NSSb and the upper nanosheet stack NSSt, have different sizes from each other in the first horizontal direction (X direction). For example, in the first horizontal direction (X direction), a length of each of the first nanosheet Nb1 and the second nanosheet Nb2, which are relatively close to an upper surface of the fin-type active area FA, among the first nanosheet Nb1, the second nanosheet Nb2, the third nanosheet Nt1, and the fourth nanosheet Nt2 may be less than a length of the third nanosheet Nt1 and the fourth nanosheet Nt2, which are relatively far from the upper surface of the fin-type active area FA.

An intermediate insulating layer MDI may be arranged between the lower nanosheet stack NSSb and the upper nanosheet stack NSSt. The intermediate insulating layer MDI may include an insulating material.

The plurality of nanosheet separation walls 122 may extend in parallel with each other in the first horizontal direction (X direction). Each of a plurality of nanosheet separation walls 122 may protrude from the upper surface of the substrate 102 in the vertical direction (Z direction). Both sidewalls of the nanosheet separation wall 122 may be in contact with the fin-type active area FA, the lower nanosheet stack NSS, and the intermediate insulating layer MDI. A pair of nanosheet stacks NSS facing each other in the second horizontal direction (Y direction) may be arranged spaced apart from each other with one nanosheet separation wall 122 therebetween in the second horizontal direction (Y direction). In some implementations, a lower surface of the nanosheet separation wall 122 is at the same vertical level as the upper surface of the substrate 102. In some implementations, the upper surface of the nanosheet separation wall 122 is at a higher vertical level than the lower surface of the intermediate insulating layer MDI, and is at a lower vertical level than the upper surface of the intermediate insulating layer MDI. In some implementations, the nanosheet separation wall 122 includes an insulating material. For example, the insulating material may include SiCN, SiBCN, or a combination thereof.

A gate separation spacer 126 may be arranged on one sidewall relatively distant from one nanosheet separation wall 122 in the second horizontal direction (Y direction), among both sidewalls of each of a pair of upper nanosheet stacks NSSt, each of which is arranged on a pair of lower nanosheet stacks NSSb which include the one nanosheet separation wall 122 therebetween and are apart from each other in the second horizontal direction (Y direction). The gate separation spacer 126 may extend in parallel with each other in the second horizontal direction (Y direction). In some implementations, the lower surface of the gate separation spacer 126 is at a higher vertical level than a lower surface of the intermediate insulating layer MDI, and is at a lower vertical level than the upper surface of the intermediate insulating layer MDI. In some implementations, the gate separation spacer 126 is at a higher vertical level than each of an upper surface of an upper gate metal layer GMt and an upper surface of a lower gate metal layer GMb. The upper gate metal layer GMt and the lower gate metal layer GMb may be insulated from each other by the gate separation spacer 126. In some implementations, the gate separation spacer 126 includes an insulating material. The insulating material may include, for example, SiCN, SiBCN, or a combination thereof. In some implementations, the gate separation spacer 126 includes substantially the same material as the nanosheet separation wall 122. For example, the gate separation spacer 126 and the nanosheet separation wall 122 may include SiCN.

The plurality of gate lines GL may include a first gate metal layer 140b, a second gate metal layer 140t, and a third gate metal layer GM. The first gate metal layer 140b (sometimes referred to as a “first metal layer 140b”) may be arranged between the fin-type active area FA and the first nanosheet Nb1, between the first nanosheet Nb1 and the second nanosheet Nb2, and between the second nanosheet Nb2 and the intermediate insulating layer MDI. The second gate metal layer 140t (sometimes referred to as a “second metal layer 140t”) may be arranged between the intermediate insulating layer MDI and the third nanosheet Nt1 and between the third nanosheet Nt1 and the fourth nanosheet Nt2. The third gate metal layer GM (sometimes referred to as a “third metal layer GM”) may include the lower gate metal layer GMb and the upper gate metal layer GMt. The lower gate metal layer GMb may cover one relatively distant sidewall on the one nanosheet separation wall 122 in the second horizontal direction (Y direction), among both sidewalls of each of a pair of lower nanosheet stacks NSSb which include one nanosheet separation wall 122 therebetween and are apart from each other in the second horizontal direction (Y direction). The upper gate metal layer GMt may cover one sidewall relatively close to the one nanosheet separation wall 122 in the second horizontal direction (Y direction), among both sidewalls of each of the pair of upper nanosheet stacks NSSt respectively arranged on the pair of lower nanosheet stacks NSSb, and may cover an upper surface of the fourth nanosheet Nt2. The lower gate metal layer GMb and the upper gate metal layer GMt may be spaced apart from each other with the gate separation spacer 126 therebetween in the second horizontal direction (Y direction).

The third metal layer GM may include, for example, a metal, conductive metal nitride, conductive metal carbide, conductive metal silicide, or a combination thereof. For example, the third gate metal layer GM may include Al, Cu, Ti, Ta, W, Mo, TaN, NiSi, CoSi, TiN, WN, TiAl, TiAlN, TaCN, TaC, TaSiN, or a combination thereof, but is not limited thereto.

The first metal layer 140b may include a metal, conductive metal nitride, conductive metal carbide, conductive metal silicide, that are doped with a p-type dopant, or a combination thereof. For example, the first metal layer 140b may include Al, Cu, Ti, Ta, W, Mo, TaN, NiSi, CoSi, TiN, WN, TiAl, TiAlN, TaCN, TaC, TaSiN, that are doped with a p-type dopant, or a combination thereof. The p-type dopant may include, for example, boron (B).

The second metal layer 140t may include a metal, conductive metal nitride, conductive metal carbide, conductive metal silicide, that are doped with an n-type dopant, or a combination thereof. For example, the first metal layer 140b may include Al, Cu, Ti, Ta, W, Mo, TaN, NiSi, CoSi, TiN, WN, TiAl, TiAlN, TaCN, TaC, TaSiN, that are doped with an n-type dopant, or a combination thereof. The p-type dopant may include, for example, arsenide (As) or phosphorus (P).

The first metal layer 140b and the lower gate metal layer GMb may constitute one gate connected to one lower nanosheet stack NSSb, and the second metal layer 140t and the upper gate metal layer GMt may constitute another gate connected to one upper nanosheet stack NSSt arranged on the one lower nanosheet stack NSSb. Accordingly, the lower gate metal layer GMb and the upper gate metal layer GMt may be insulated from each other by the gate separation spacer 126, and the lower gate metal layer GMb and the upper gate metal layer GMt, which are insulated from each other, may constitute separate gates.

A first spacer 142b may be arranged on both sidewalls of the first metal layer 140b, and a second spacer 142t may be arranged on both sidewalls of the second metal layer 140t. Each of the first spacer 142b and the second spacer 142t may extend in parallel with each other in the second horizontal direction (Y direction). Each of the first spacer 142b and the second spacer 142t may include, for example, a nitride (e.g., silicon nitride).

A gate insulating layer 130 may be arranged between the fin-type active area FA and the first nanosheet Nb1, each of the first nanosheet Nb1 and the second nanosheet Nb2 and the first metal layer 140b, each of the first nanosheet Nb1 and the second nanosheet Nb2 and the lower gate metal layer GMb, between the first metal layer 140b and the intermediate insulating layer MDI, between each of the third nanosheet Nt1 and the fourth nanosheet Nt2 and the second metal layer 140t, between each of the third nanosheet Nt1 and the fourth nanosheet Nt2 and the upper gate metal layer GMt. In addition, the gate insulating layer 130 may cover at least a portion of the upper surface of the nanosheet separation wall 122, and may cover at least a portion of the surface of the gate separation spacer 126.

In some implementations, the gate insulating layer 130 includes a silicon oxide layer, a silicon oxynitride layer, a high-k dielectric layer having a dielectric constant higher than that of the silicon oxide layer, or a combination thereof. The high-k dielectric layer may include a metal oxide or a metal oxynitride. For example, the high-k layer may include HfO₂, HfSiO, HfSiON, HfTaO, HfTiO, HfZrO, ZrO₂, Al₂O₃, or a combination thereof, but is not limited thereto.

A gate capping layer 150 may be arranged on the third metal layer GM of the gate line GL. The gate capping layer 150 may cover an upper surface of the third metal layer GM. The gate capping layer 150 may extend on the third metal layer GM in the second horizontal direction (Y direction). In some implementations, the gate capping layer 150 includes silicon nitride or silicon oxynitride.

A first gate spacer CLD1 and a second gate spacer CLD2 may be sequentially arranged on both sidewalls of the third metal layer GM and the gate capping layer 150. The first gate spacer CLD1 and the second gate spacer CLD2 may cover both sidewalls of the third metal layer GM and the gate capping layer 150. The first gate spacer CLD1 and the second gate spacer CLD2 may extend on the substrate 102 in the second horizontal direction (Y direction).

In some implementations, each of the first gate spacer CLD1 and the second gate spacer CLD2 includes silicon oxide, silicon nitride, silicon oxynitride, silicon carbide, silicon oxide nitride, or a combination thereof.

A gate cut structure CT may extend in the first horizontal direction (X direction). The gate cut structure CT may cut (e.g., extend between) at least a portion of the gate lines GL adjacent to each other. The gate cut structure CT may include a first gate cut structure CTn and a second gate cut structure CTw. The first gate cut structure CTn may penetrate the gate capping layer 150 and the upper gate metal layer GMt to extend in the vertical direction (Z direction). The first gate cut structure CTn may be in contact with the upper surface of the nanosheet separation wall 122 on a bottom surface thereof. The first gate cut structure CTn may cut the upper gate metal layer GMt between a pair of upper nanosheet stacks NSSt respectively arranged on a pair of lower nanosheet stacks NSSb which include one nanosheet separation wall 122 therebetween and are apart from each other in the second horizontal direction (Y direction). The second gate cut structure CTw may penetrate the gate capping layer 150 and the lower gate metal layer GMb to extend in the vertical direction (Z direction). The second gate cut structure CTw may be in contact with the upper surface of the device separation layer 112 on a bottom surface thereof. The second gate cut structure CTw may cut the upper gate metal layer GMt between a pair of nanosheet stacks NSS (e.g., including NSSt and NSSb) including one nanosheet separation wall 122 and spaced apart from each other in the second horizontal direction (Y direction) and another pair of nanosheet stacks NSS adjacent to the pair of the nanosheet stacks NSS. The first gate cut structure CTn and the second gate cut structure CTw may include, for example, silicon nitride.

In some implementations, a second horizontal direction length of the first gate cut structure CTn is less than a second horizontal direction length of the second gate cut structure CTw. For example, the second horizontal direction length of the first gate cut structure CTn may be about 5 nm to about 10 nm, and the second horizontal direction length of the second gate cut structure CTw may be about 15 nm to about 35 nm.

A lower source/drain area SDb may be arranged between the lower nanosheet stacks NSSb apart from each other in the first horizontal direction (X direction), and an upper source/drain area SDt may be arranged between the upper nanosheet stacks NSSt arranged on the lower nanosheet stack NSSb. The lower source/drain area SDb may extend into the fin-type active area FA. The lower source/drain area SDb may be connected to both ends of the lower nanosheet stack NSSb, and the upper source/drain area SDt may be connected to both ends of the upper nanosheet stack NSSt. In some implementations, the lower source/drain area SDb and the upper source/drain area SDt include a doped Si layer, a doped SiGe layer, a doped Ge layer, a doped SiC layer, or a doped InGaAs layer, but are not limited thereto. In some implementations, the lower source/drain area SDb and the upper source/drain area SDt include dopants of different conductivity types. For example, the lower source/drain area SDb may include an n-type dopant, and the upper source/drain area SDt may include a p-type dopant. The lower source/drain area SDb may form an n-type metal oxide semiconductor (NMOS) transistor together with the lower nanosheet stack NSSb, and the upper source/drain area SDt may form a p-type metal oxide semiconductor (PMOS) transistor together with the upper nanosheet stack NSSt.

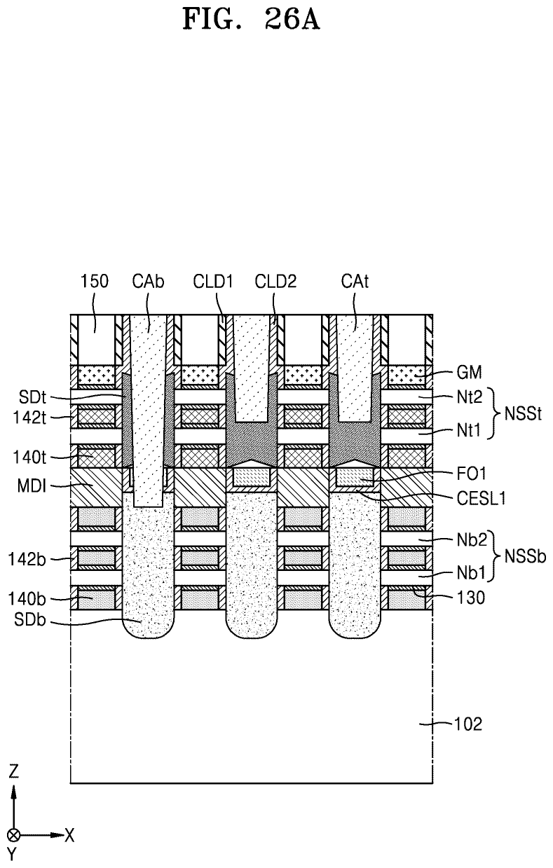

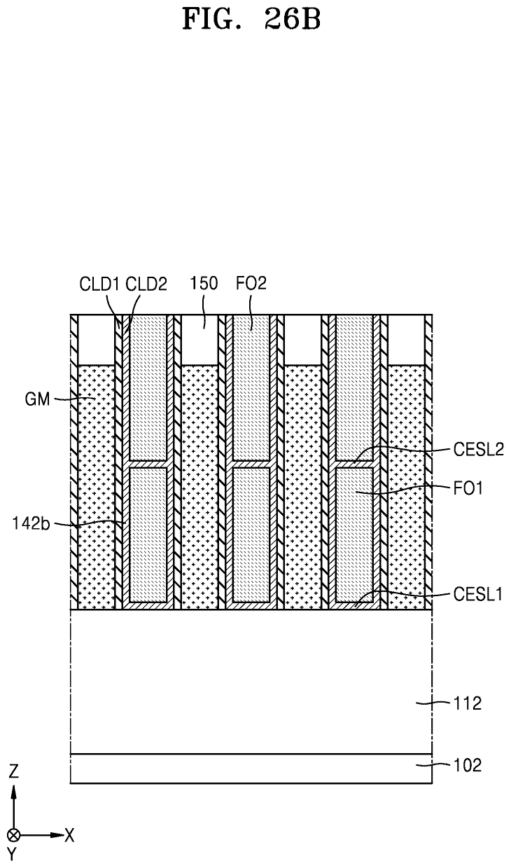

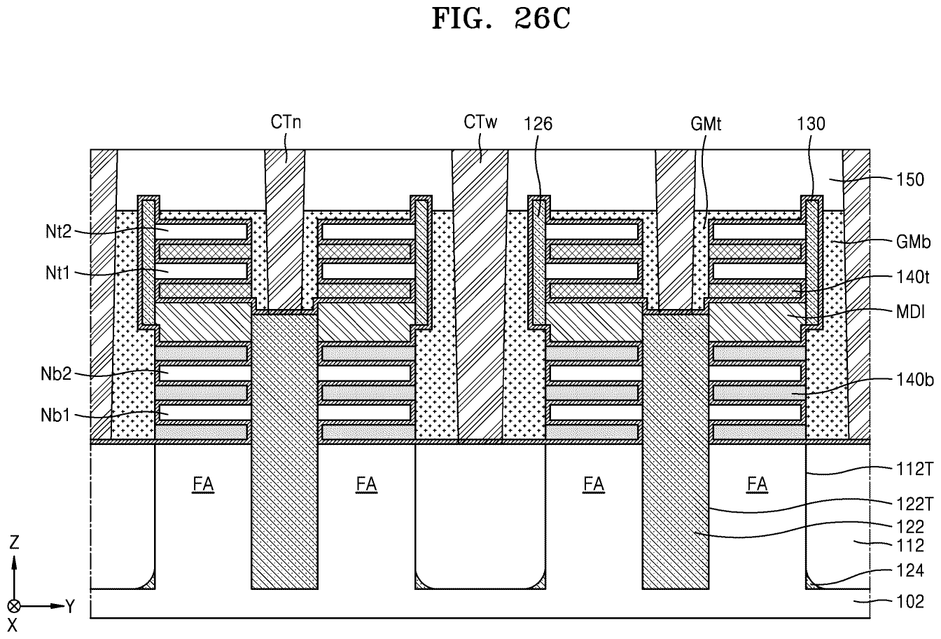

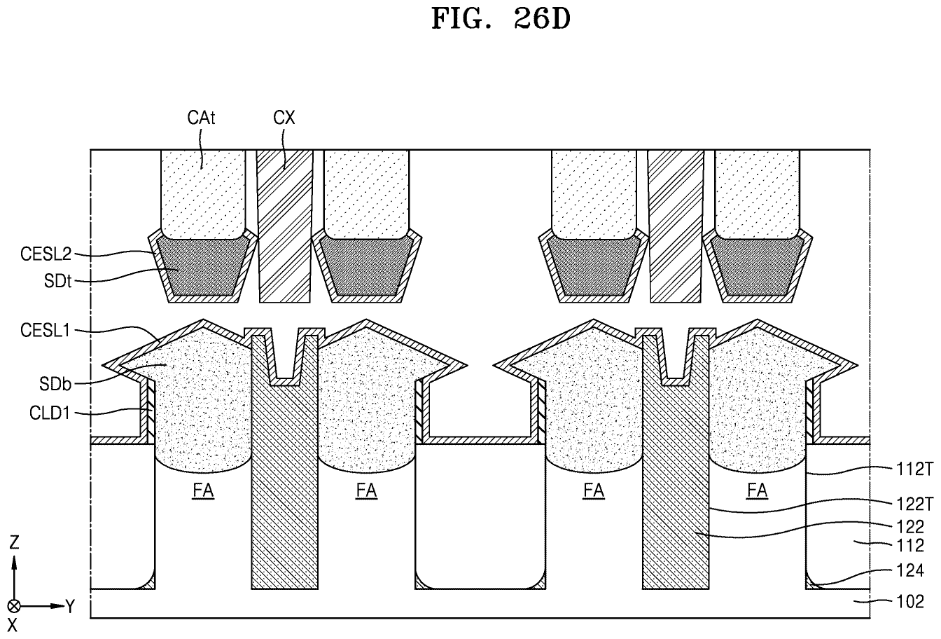

A first etching stop layer CESL1 may cover a surface of the lower source/drain area SDb. A second etching stop layer CESL2 (refer to FIG. 26D) may cover a surface of the upper source/drain area SDt. Each of the first etching stop layer CESL1 and the second etching stop layer CESL2 may include, for example, a nitride layer. A first interlayer insulating layer FO1 may be arranged on the first etching stop layer CESL1, and may cover the first etching stop layer CESL1. A second interlayer insulating layer FO2 (refer to FIG. 26D) may be arranged on the second etching stop layer CESL2, and may cover the second etching stop layer CESL2. Each of the first interlayer insulating layer FO1 and the second interlayer insulating layer FO2 may include, for example, silicon oxide or an insulating material having a lower dielectric constant than silicon oxide. In some implementations, each of the first interlayer insulating layer FO1 and the second interlayer insulating layer FO2 includes a tetraethyl orthosilicate (TEOS) layer or an ultra-low dielectric constant (ULK) layer having an ultra-low dielectric constant K of about 2.2 to about 2.4. The ULK layer may include an SiOC layer or an SiCOH layer.

A plurality of gate contacts CB may penetrate the gate capping layer 150 to be in contact with the third metal layer GM of the gate line GL. Each of the plurality of gate contacts CB may include a first gate contact CBb and a second gate contact CBt. The first gate contact CBb may be in contact with the lower gate metal layer GMb, and the second gate contact CBt may be in contact with the upper gate metal layer GMt. The first gate contact CBb may be connected to a gate including the lower gate metal layer GMb and the first metal layer 140b, and the second gate contact CBt may be connected to a gate including the upper gate metal layer GMt and the second metal layer 140t.

A plurality of source/drain contacts CA may penetrate the second interlayer insulating layer FO2 (refer to FIG. 26D) and/or the first interlayer insulating layer FO1 to be in contact with the upper source/drain area SDt or the lower source/drain area SDb. Each of the plurality of source/drain contacts CA may include a first source/drain contact CAb and a second source/drain contact CAt. The first source/drain contact CAb may penetrate the first interlayer insulating layer FO1 and the second interlayer insulating layer FO2 to be in contact with the lower source/drain area SDb. The second source/drain contact CAt may penetrate the second interlayer insulating layer FO2 to be in contact with the upper source/drain area SDt.

In some implementations, each of the plurality of gate contacts CB and the plurality of source/drain contacts CA includes a metal, conductive metal nitride, or a combination thereof. For example, each of the plurality of gate contacts CB and the plurality of source/drain contacts CA may include a metal material, such as W, Al, Cu, Ti, Ta, Ru, Mn, and Co, metal nitride, such as TiN, TaN, CoN, and WN, or an alloy (e.g., a conductive alloy), such as cobalt tungsten phosphide (CoWP), cobalt tungsten boron (CoWB), and cobalt tungsten boron phosphide (CoWBP).

A contact cut structure CX (refer to FIG. 26D) may penetrate the second interlayer insulating layer FO2 and may be in contact with the upper surface of the first interlayer insulating layer FO1. The second source/drain contact CAt may be horizontally apart from each other with the contact cut structure CX therebetween. The contact cut structure CX may include, for example, silicon nitride.

The semiconductor device 100 may include the nanosheet separation wall 122 arranged between a pair of nanosheet stacks NSS and the gate separation spacer 126 arranged on both sidewalls of the pair of nanosheet stacks NSS. A pair of nanosheet stacks NSS may be apart from each other by the nanosheet separation wall 122 to improve parasitic capacitance of the semiconductor device 100. In addition, because the upper gate metal layer GMt is separated by the gate separation spacer 126, each of the lower nanosheet stack NSSb and the upper nanosheet stack NSSt, which are included in the nanosheet stack NSS, may be connected to a separate gate. Accordingly, in some implementations, operating characteristics of the semiconductor device 100 may be improved.

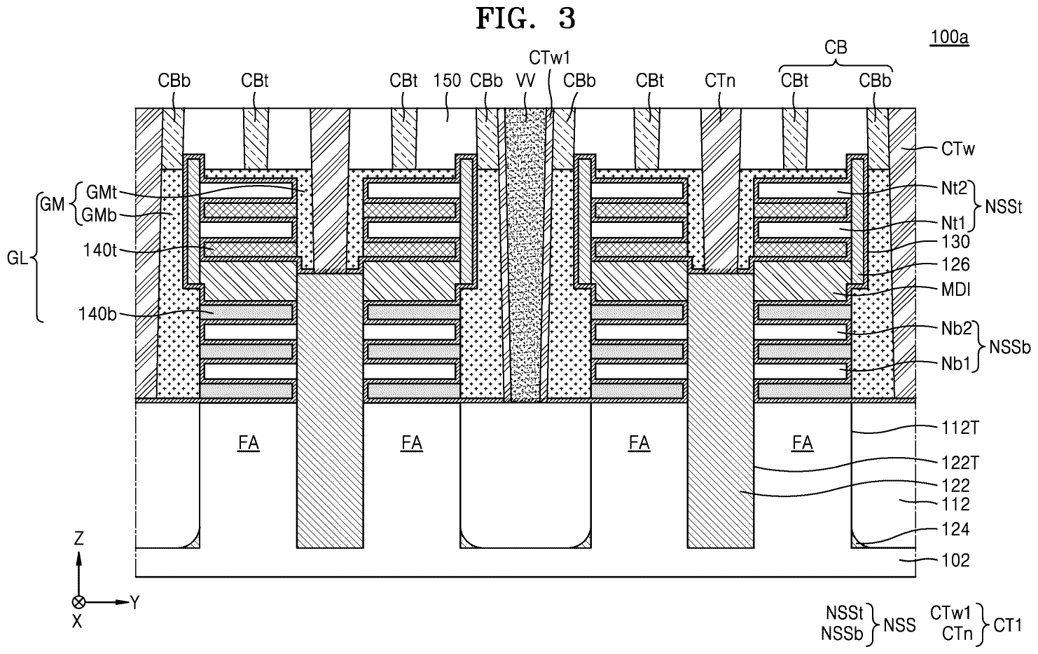

FIG. 3 is a cross-sectional view of a semiconductor device 100a. Because components of the semiconductor device 100a illustrated in FIG. 3 are similar to components of the semiconductor device 100 illustrated in FIGS. 1, 2A, and 2B, differences thereof are mainly described below; the characteristics of the semiconductor device 100a are the same as those described for the semiconductor device 100, except where noted otherwise or suggested otherwise by context.

Referring to FIG. 3, the semiconductor device 100a may have a configuration substantially similar to the configuration of the semiconductor device 100 illustrated in FIGS. 1, 2A, and 2B, except that the semiconductor device 100a includes a gate cut structure CT1 including the first gate cut structure CTn and a second gate cut structure CTw1 and includes a vertical via VV penetrating the second gate cut structure CTw1.

The semiconductor device 100a may include the vertical via VV which penetrates the second gate cut structure CTw1 and extends in the vertical direction (Z direction). The second gate cut structure CTw1 and the vertical via VV may extend into the device separation layer 112. The vertical via VV may include, for example, a conductive metal. For example, the vertical via VV may include W. In some implementations, the second horizontal direction length of the vertical via VV ia about 10 nm. The vertical via VV may provide an electrical connection path between transistors included in the semiconductor device 100a.

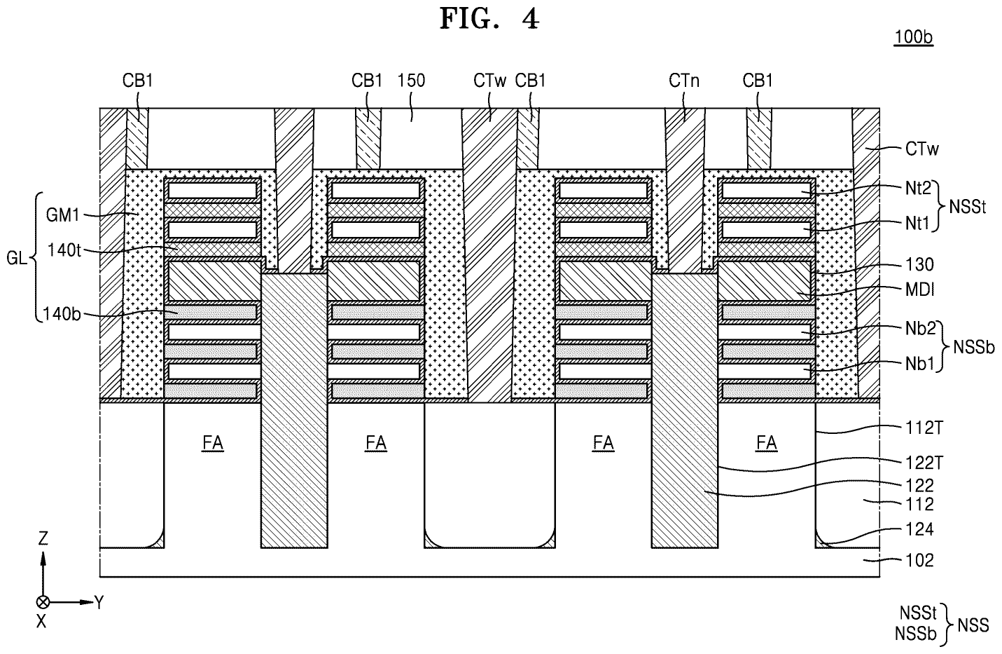

FIG. 4 is a cross-sectional view of a semiconductor device 100b. Because components of the semiconductor device 100b illustrated in FIG. 4 are similar to components of the semiconductor device 100 illustrated in FIGS. 1, 2A, and 2B, differences thereof are mainly described below; the characteristics of the semiconductor device 100b are the same as those described for the semiconductor device 100, except where noted otherwise or suggested otherwise by context.

Referring to FIG. 4, the semiconductor device 100b may have a configuration substantially similar to the configuration of the semiconductor device 100 illustrated in FIGS. 1, 2A, and 2B except that the gate separation spacer 126 (refer to FIG. 2B) is not included.

The semiconductor device 100b may not include the gate separation spacer 126. Accordingly, a third metal layer GM1 may not be separated by the gate separation spacer 126. Because the third metal layer GM1 is not separated, the first metal layer 140b, the second metal layer 140t, and the third metal layer GM1 may form one gate together. One lower nanosheet stack NSSb and one upper nanosheet stack NSSt arranged on the one lower nanosheet stack NSSb may share one gate including the first metal layer 140b, the second metal layer 140t, and the third metal layer GM1. The one gate including the first metal layer 140b, the second metal layer 140t, and the third metal layer GM1 may be connected to a gate contact CB1.

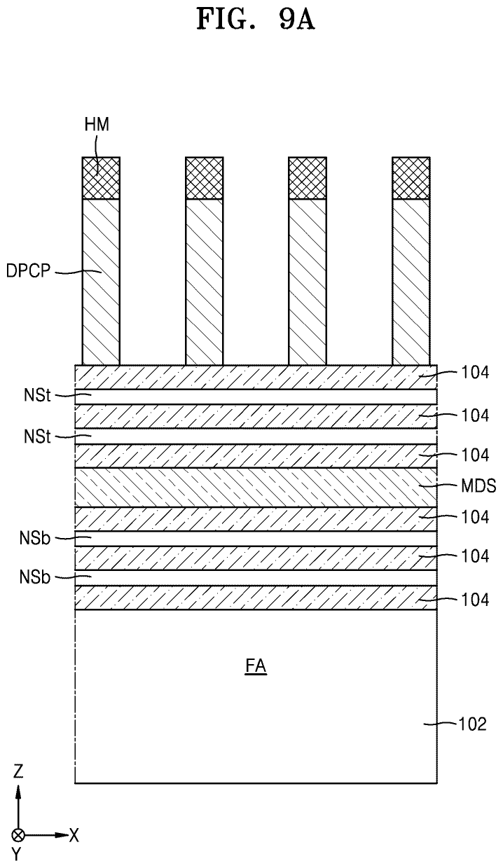

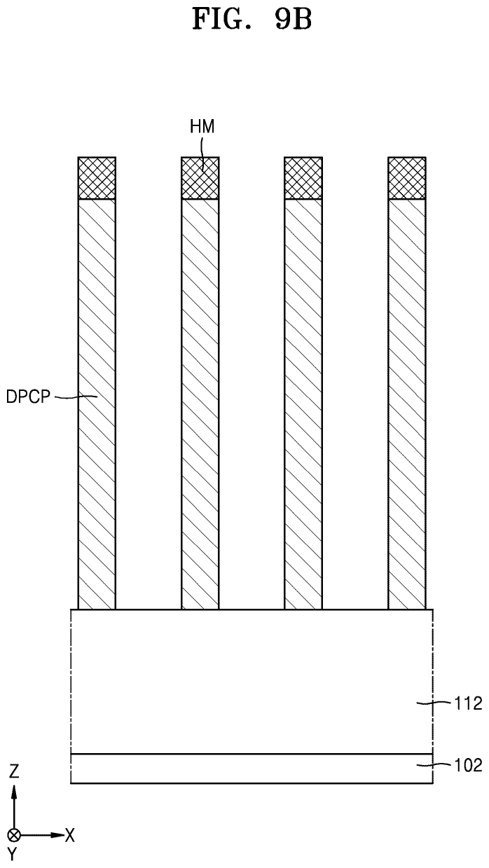

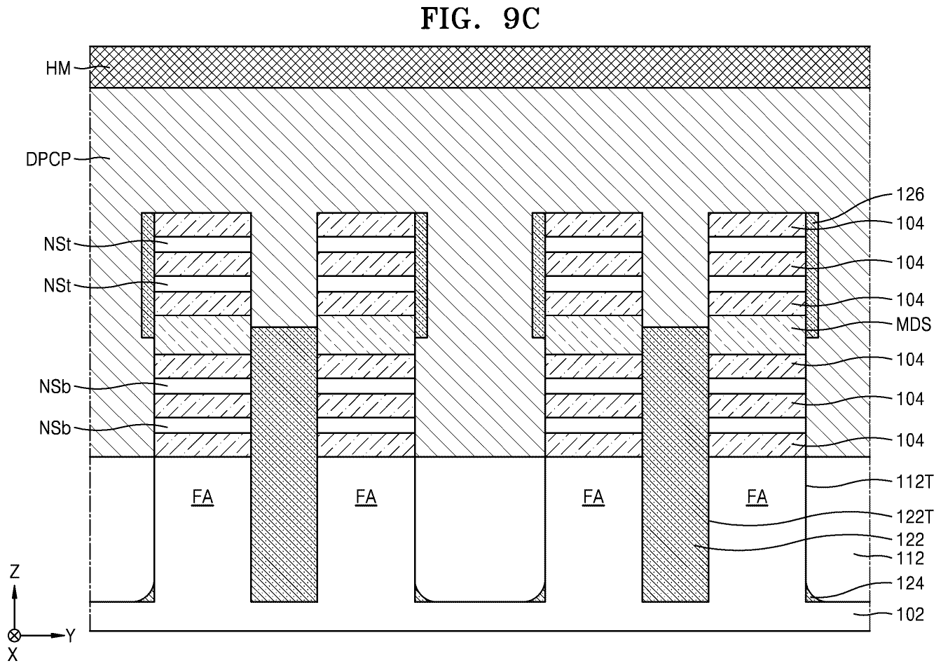

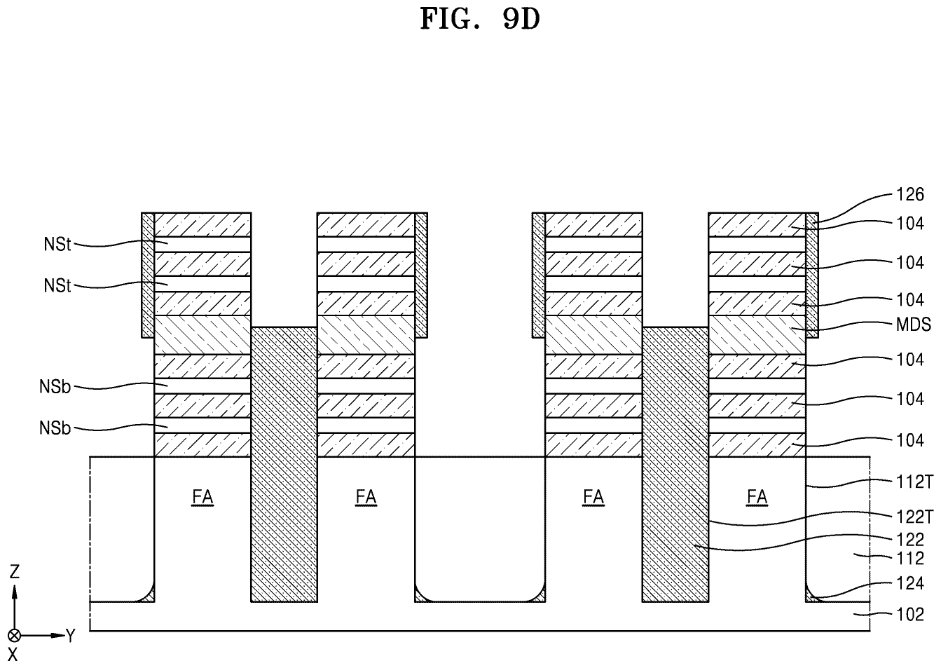

FIGS. 5A, 5B, 6A, 6B, 7A, 7B, 8A, 8B, 9A, 9B, 9C, 9D, 10A, 10B, 10C, 10D, 11A, 11B, 12A, 12B, 12C, 13A, 13B, 14A, 14B, 14C, 15A, 15B, 15C, 16A, 16B, 16C, 17A, 17B, 17C, 18A, 18B, 18C, 19A, 19B, 20A, 20B, 21A, 21B, 22A, 22B, 23A, 23B, 23C, 24A, 24B, 24C, 25A, 25B, 25C, 25D, 26A, 26B, 26C, and 26D are cross-sectional views of a manufacturing method of a semiconductor device, e.g., the semiconductor device 100. FIGS. 5A, 6A, 7A, 8A, 9A, 10A, 11A, 12A, 13A, 14A, 15A, 16A, 17A, 18A, 19A, 20A, 21A, 22A, 23A, 24A, 25A, and 26A are cross-sectional views taken along line X1-X1′ in FIG. 1; FIGS. 9B, 10B, 12B, 14B, 15B, 16B, 17B, 18B, 23B, 24B, 25B, and 26B are cross-sectional views taken along line X2-X2′ in FIG. 1; FIGS. 5B, 6B, 7B, 8B, 9C, 10C, 18C, 19B, 21B, 22B, 23C, 24C, 24C, 25C, and 26C are cross-sectional views taken along line Y1-Y1′ in FIG. 1; and FIGS. 9D, 10D, 11D, 12C, 13B, 14C, 15C, 16D, 17C, 25D, and 26D are cross-sectional views taken along line Y2-Y2′ in FIG. 1.

Referring to FIGS. 5A and 5B, firstly, a plurality of sacrificial layers 104 and a plurality of lower nanosheet semiconductor layers NSb may be alternately stacked on the substrate 102, and after an intermediate sacrificial layer MDS is formed, the plurality of sacrificial layers 104 and a plurality of upper nanosheet semiconductor layers NSt may be alternately stacked on the intermediate sacrificial layer MDS. Each of the plurality of sacrificial layers 104, the plurality of lower nanosheet semiconductor layers NSb, the plurality of upper nanosheet semiconductor layers NSt, and the intermediate sacrificial layer MDS may extend in parallel with the upper surface of the substrate 102.

Next, after a plurality of hard mask patterns are formed on a stacked structure of the plurality of sacrificial layers 104, the plurality of lower nanosheet semiconductor layers NSb, the plurality of upper nanosheet semiconductor layers NSt, and the intermediate sacrificial layer MDS, the plurality of sacrificial layers 104, the plurality of lower nanosheet semiconductor layers NSb, the plurality of upper nanosheet semiconductor layers NSt, and the intermediate sacrificial layer MDS may be patterned by using the plurality of hard mask patterns as an etching mask, and by removing a portion of the semiconductor substrate 102 exposed between the patterned resultant product together, a plurality of device separation layer trenches 112T and a plurality of separation recesses 122T may be formed. Each of the plurality of hard mask patterns may include nitride. For example, each of the plurality of hard mask patterns may include silicon nitride. After the plurality of device separation layer trenches 112T and the plurality of separation recesses 122T are formed, the plurality of hard mask patterns may be removed.

Each of the plurality of device separation layer trenches 112T and the plurality of separation recesses 122T may extend in the first horizontal direction (X direction). In some implementations, the plurality of device separation layer trenches 112T and the plurality of separation recesses 122T are formed to be alternately arranged in the second horizontal direction (Y direction).

Next, an insulating material layer 120M may be formed, which fills the plurality of separation recesses 122T and covers surfaces of the substrate 102, the plurality of sacrificial layers 104, the plurality of lower nanosheet semiconductor layers NSb, the plurality of upper nanosheet semiconductor layers NSt, and the intermediate sacrificial layer MDS. The insulating material layer 120M may include, for example, SiCN, SiBCN, or a combination thereof.

Referring to FIGS. 6A and 6B, from the resultant product of FIGS. 5A and 5B, a portion of the insulating material layer 120M (refer to FIG. 5A) may be removed to form the nanosheet separation wall 122 filling each of the plurality of separation recesses 122T. The nanosheet separation wall 122 may be formed by removing a portion of the insulating material layer 120M by using, for example, an etch-back process. A portion of the insulating material layer 120M which has not been removed by using the etch-back process may remain at a lower edge of each of the plurality of device separation layer trenches 112T. The insulating material remaining at the lower edge of each of the plurality of device separation layer trenches 112T may be referred to as the residual insulating material 124. The upper surface of the nanosheet separation wall 122 formed by using the etch-back process may be at a lower vertical level than the upper surface of the intermediate sacrificial layer MDS, and may be at a higher vertical level than the lower surface of the intermediate sacrificial layer MDS.

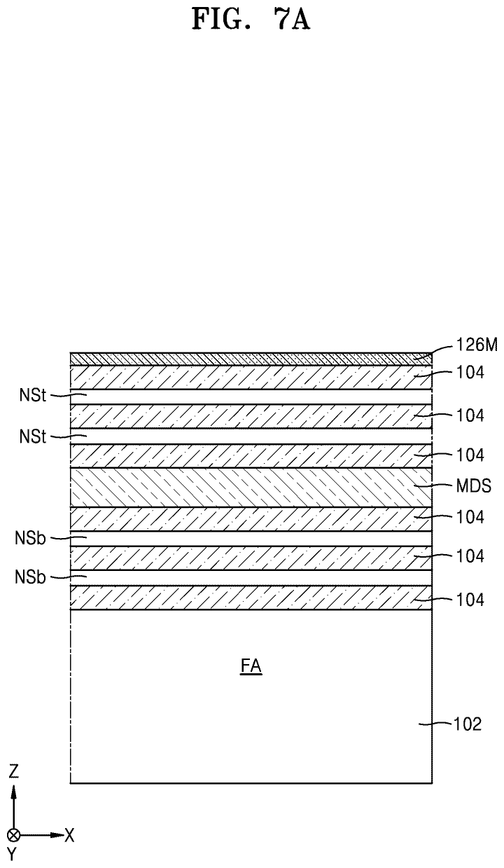

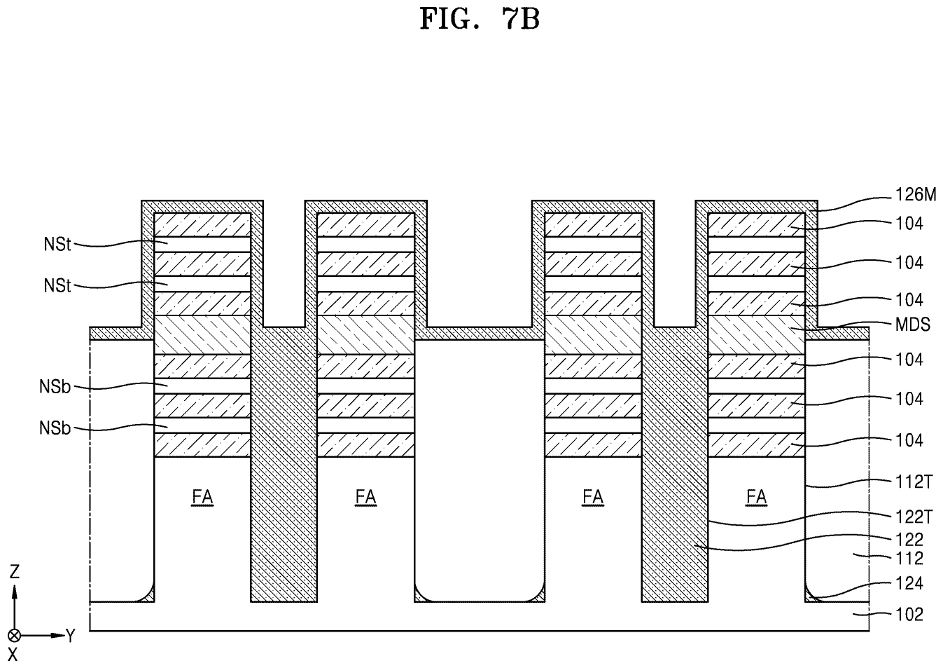

Referring to FIGS. 7A and 7B, in the resultant product of FIGS. 6A and 6B, the plurality of device separation layer trenches 112T may be filled with an insulating material to form the device separation layer 112. In this case, the upper surface of the formed device separation layer 112 may be at a lower vertical level than the upper surface of the intermediate sacrificial layer MDS, and may be at a higher vertical level than the lower surface of the intermediate sacrificial layer MDS.

Next, an insulating material layer 126M covering a surface of each of the device separation layer 112, the plurality of sacrificial layers 104, the plurality of upper nanosheet semiconductor layers NSt, and the intermediate sacrificial layer MDS may be formed. The insulating material layer 126M may include, for example, SiCN, SiBCN, or a combination thereof.

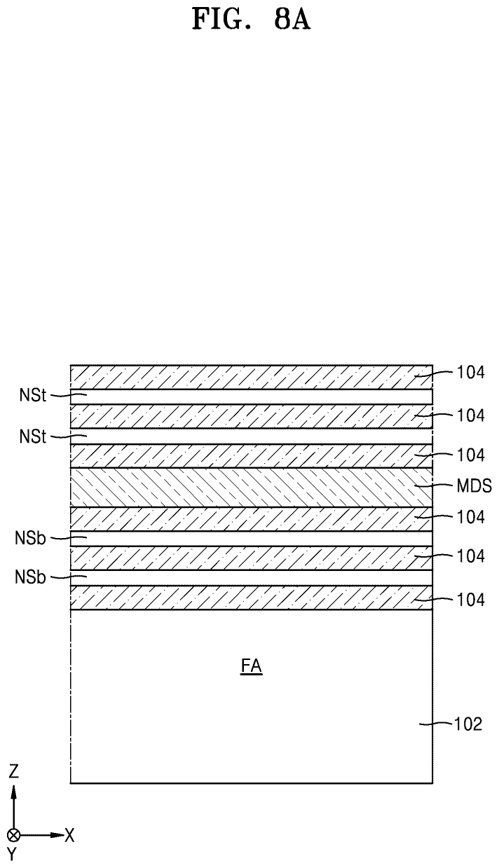

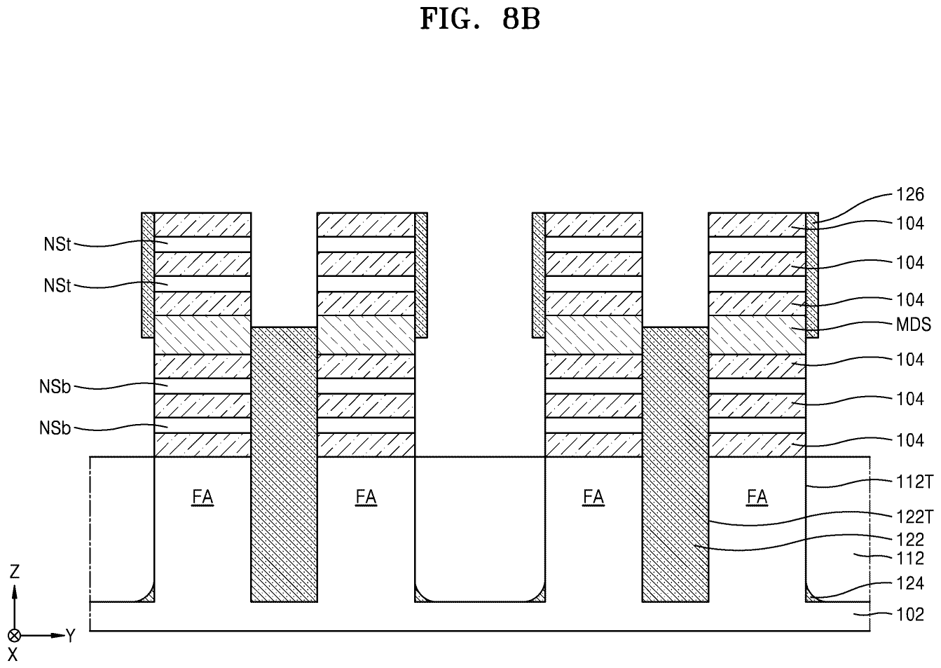

Referring to FIGS. 8A and 8B, from the resultant product of FIGS. 7A and 7B, a portion of the insulating material layer 126M may be removed to form the gate separation spacer 126. Next, a portion of the device separation layer 112 may be removed so that the upper surface of the device separation layer 112 is positioned at the same vertical level as the upper surface of the fin-type active area FA.

In some implementations, the process described with reference to FIGS. 7A and 7B and the process described with reference to FIGS. 8A and 8B may be omitted. In this case, the gate separation spacer 126 may not be formed, and after the process described with reference to FIGS. 6A and 6B is performed, and then the process to be described below with reference to FIGS. 9A through 26D is performed, the semiconductor device 100b illustrated in FIG. 4 may be formed.

Referring to FIGS. 9A, 9B, 9C, and 9D, after a dummy gate electrode DPCP and a plurality of hard mask patterns HM are sequentially formed from the resultant product of FIGS. 8A and 8B, the dummy gate electrode DPCP may be patterned by using the plurality of hard mask patterns HM as an etching mask. An upper surface of the sacrificial layer 104 at the uppermost end and the upper surface of the device separation layer 112 may be exposed by the patterned dummy gate electrode DPCP.

The plurality of hard mask patterns HM may extend in the second horizontal direction (Y direction), and may be formed apart from each other in the first horizontal direction (X direction). Each of the plurality of hard mask patterns HM may include nitride. For example, each of the plurality of hard mask patterns HM may include silicon nitride. The plurality of dummy gate electrodes DPCP respectively patterned by the plurality of hard mask patterns HM may each extend in the second horizontal direction (Y direction), and may be formed apart from each other in the first horizontal direction (X direction). The dummy gate electrode DPCP may include, for example, polysilicon, but is not limited thereto.

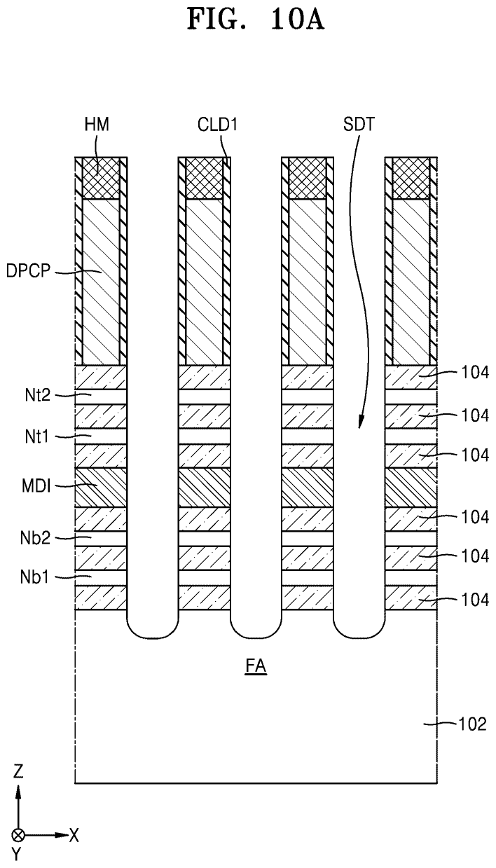

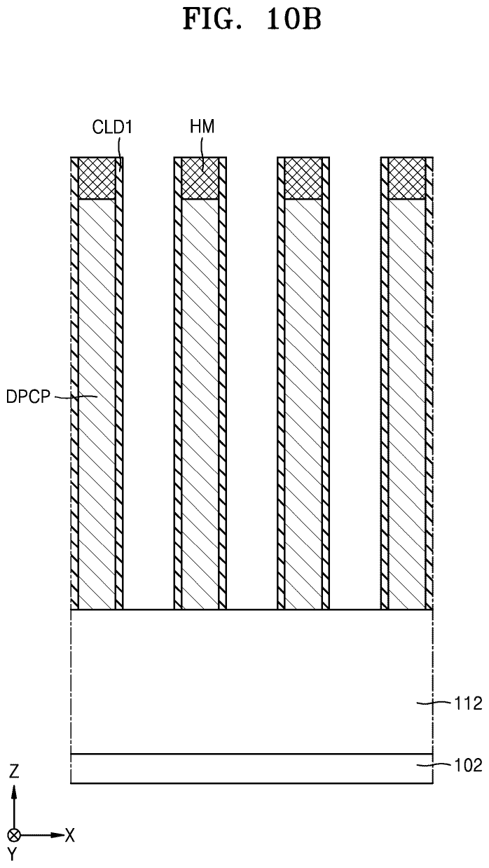

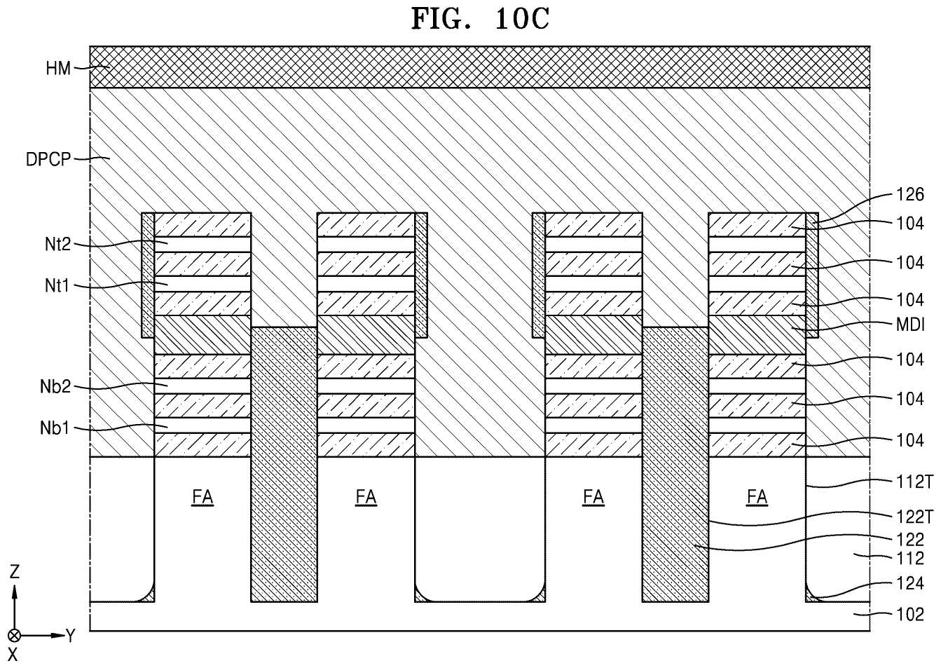

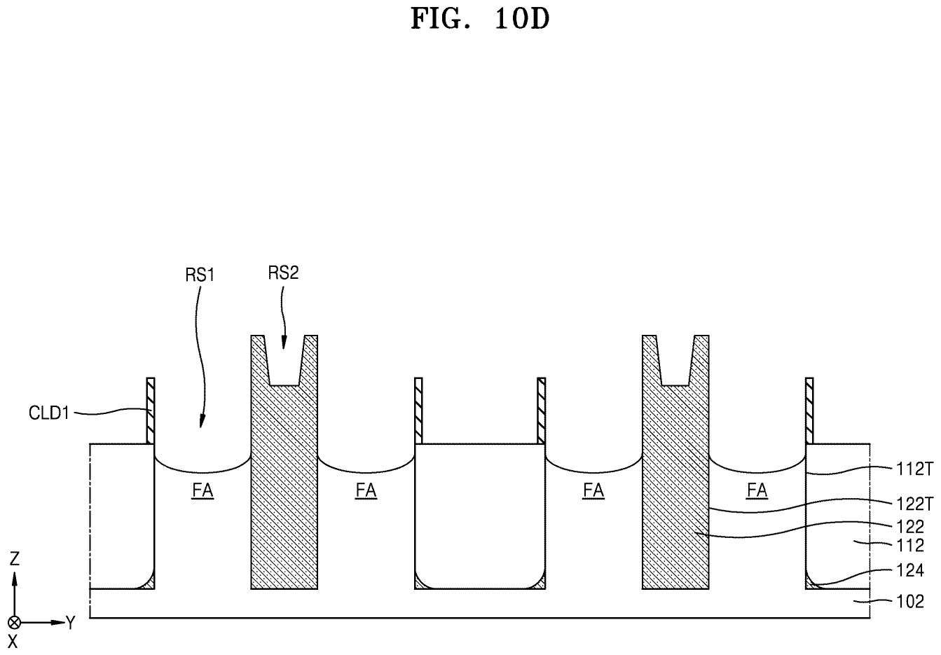

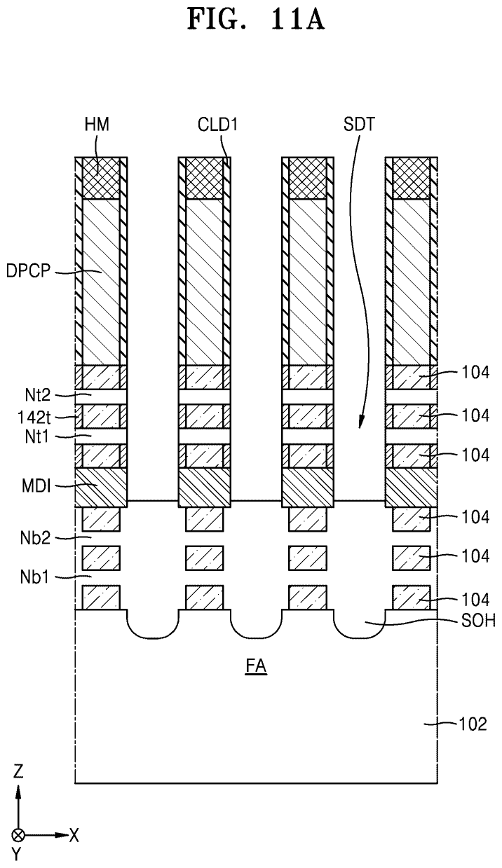

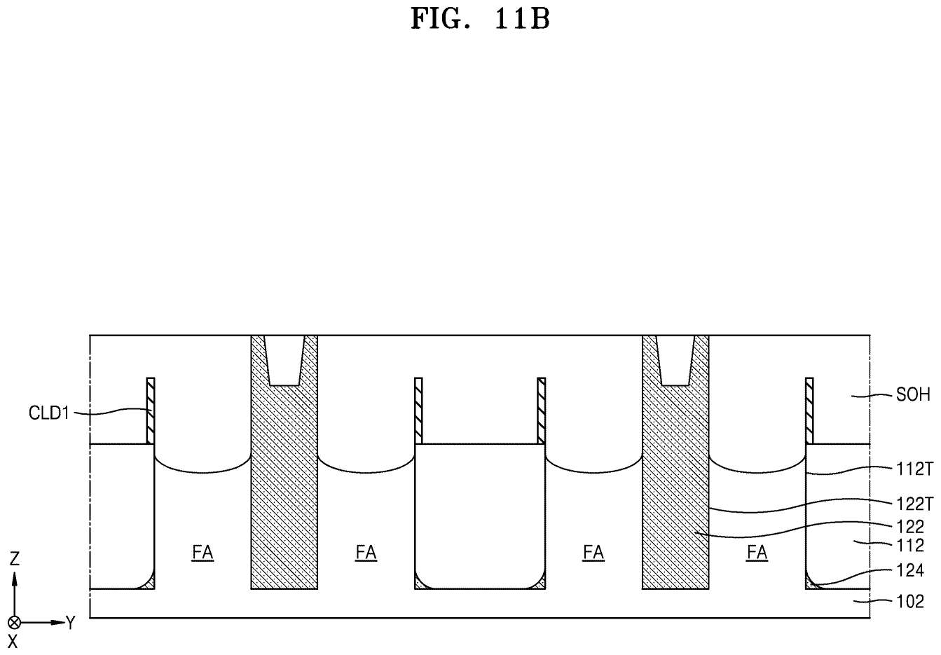

Referring to FIGS. 10A, 10B, 10C, and 10D, from the resultant product of FIGS. 9A, 9B, 9C, and 9D, the first gate spacer CLD1 covering the side surfaces of the plurality of dummy gate electrodes DPCP and the side surfaces of the plurality of hard mask patterns HM may be formed. Next, an anisotropic etching process may be performed to remove a portion of a stacked structure of the plurality of sacrificial layers 104, the plurality of lower nanosheet semiconductor layers NSb, the plurality of upper nanosheet semiconductor layers NSt, and the intermediate sacrificial layer MDS, thereby forming a first nanosheet Nb1, which are under a space between a stacked structure of the plurality of dummy gate electrodes DPCP and a plurality of hard mask patterns HM, and form the first nanosheet Nb1, the second nanosheet Nb2, a third nanosheet Nb3, and a fourth nanosheet Nb4. A plurality of source/drain trenches SDT may be defined in spaces between the first nanosheet Nb1, the second nanosheet Nb2, the third nanosheet Nb3, and the fourth nanosheet Nb4. In the process of forming the first nanosheet Nb1, the second nanosheet Nb2, the third nanosheet Nb3, and the fourth nanosheet Nb4, a portion of the fin-type active area FA may be removed to form a first recess RS1, and a portion of the nanosheet separation wall 122 may be removed to form a second recess RS2.

Next, the intermediate sacrificial layer MDS may be removed, and an intermediate insulating layer MDI may be formed by filling the space, where the intermediate sacrificial layer MDS has been removed, with an insulating material.

Referring to FIGS. 11A and 11B, from the resultant product of FIGS. 10A, 10B, 10C, and 10D, a spin-on hard mask SOH may be formed to fill the first recess RS1 formed by removing a portion of the plurality of source/drain trenches SDT and a portion of the fin-type active area FA, and the second recess RS2 formed by removing a portion of the nanosheet separation wall 122, and a portion of the spin-on hard mask SOH may be removed so that the upper surface of the spin-on hard mask SOH is at a lower vertical level than the upper surface of the intermediate insulating layer MDI while the upper surface of the spin-on hard mask SOH is at a higher vertical level than the lower surface of the intermediate insulating layer MDI.

Next, portions of the sidewalls of each of the plurality of sacrificial layers 104 formed on the intermediate insulating layer MDI may be recessed, and the second spacer 142t filling recessed spaces may be formed.

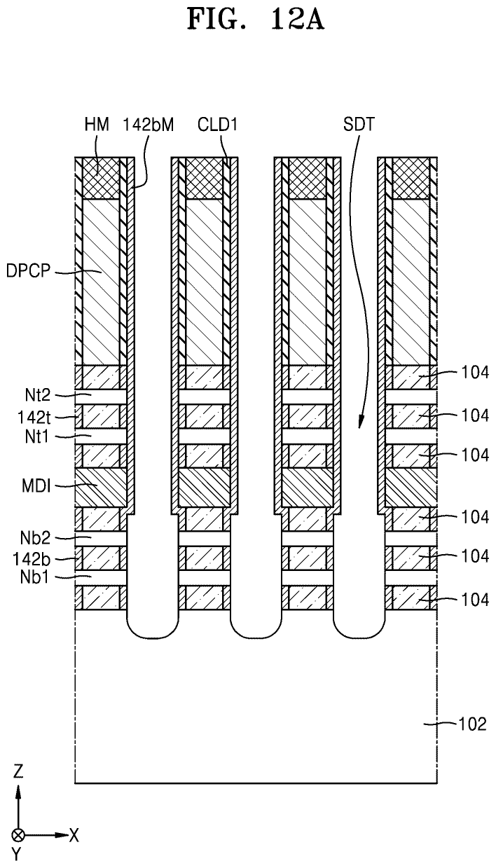

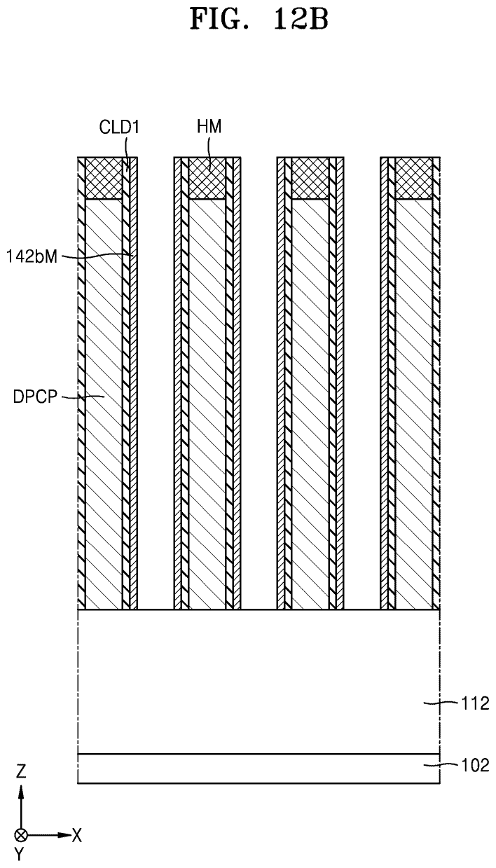

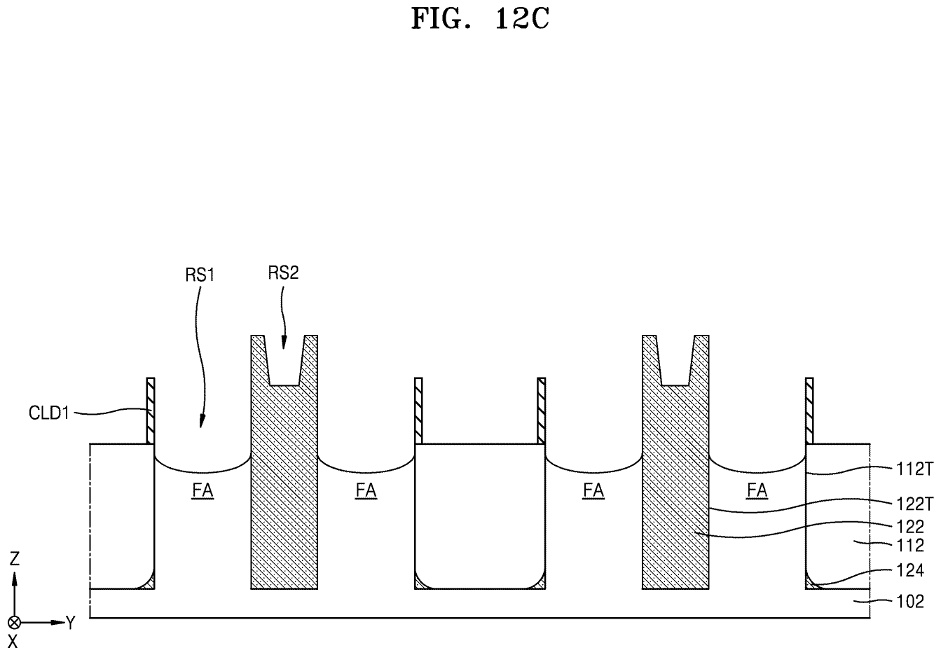

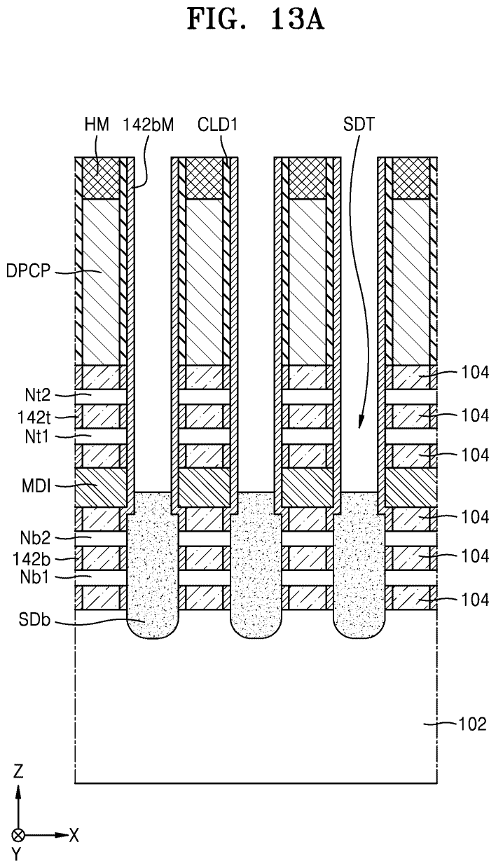

Referring to FIGS. 12A, 12B, and 12C, from the resultant product of FIGS. 11A and 11B, the spin-on hard mask SOH may be removed, portions of sidewalls of each of the plurality of sacrificial layers 104 formed under the intermediate insulating layer MDI may be recessed, and an insulating material layer 142bM filling recessed spaces may be formed. The insulating material layer 142bM may include, for example, silicon nitride.

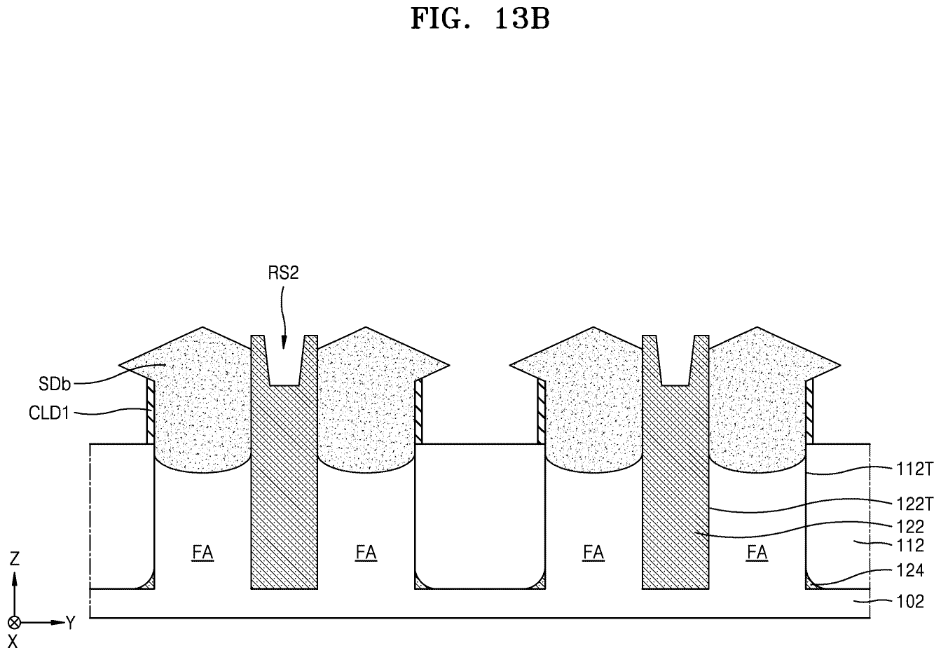

Referring to FIGS. 13A and 13B, from the resultant product of FIGS. 12A, 12B, and 12C, the lower source/drain area SDb may be formed by using an epitaxial growth from both side surfaces of each of the first nanosheet Nb1 and the second nanosheet Nb2. The lower source/drain area SDb may include, for example, an embedded SiGe structure including a plurality of epitaxially grown SiGe layers, an epitaxially grown Si layer, or an epitaxially grown SiC layer.

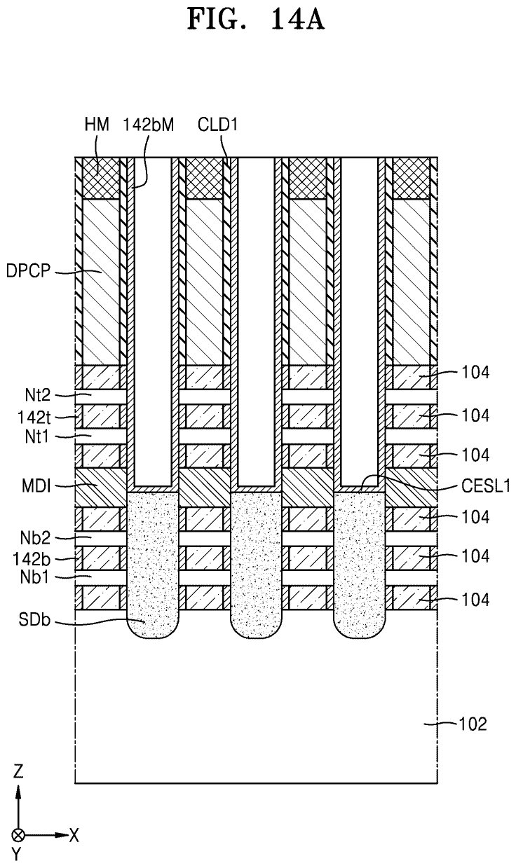

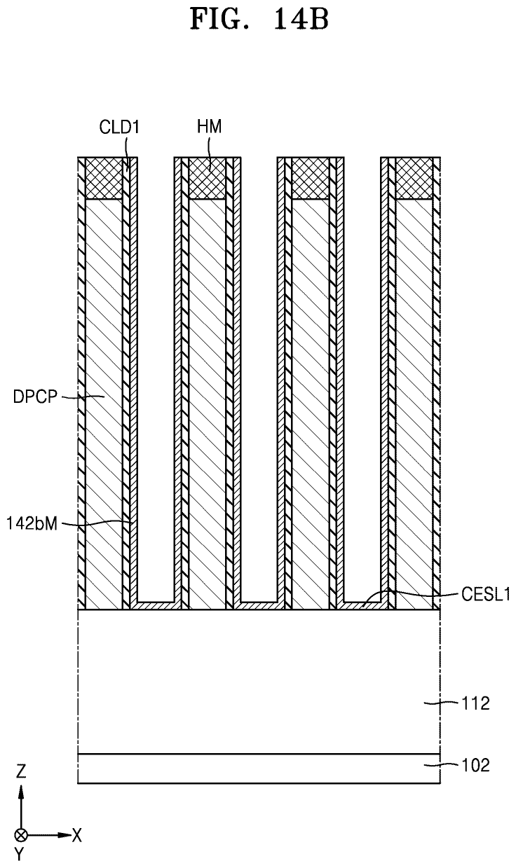

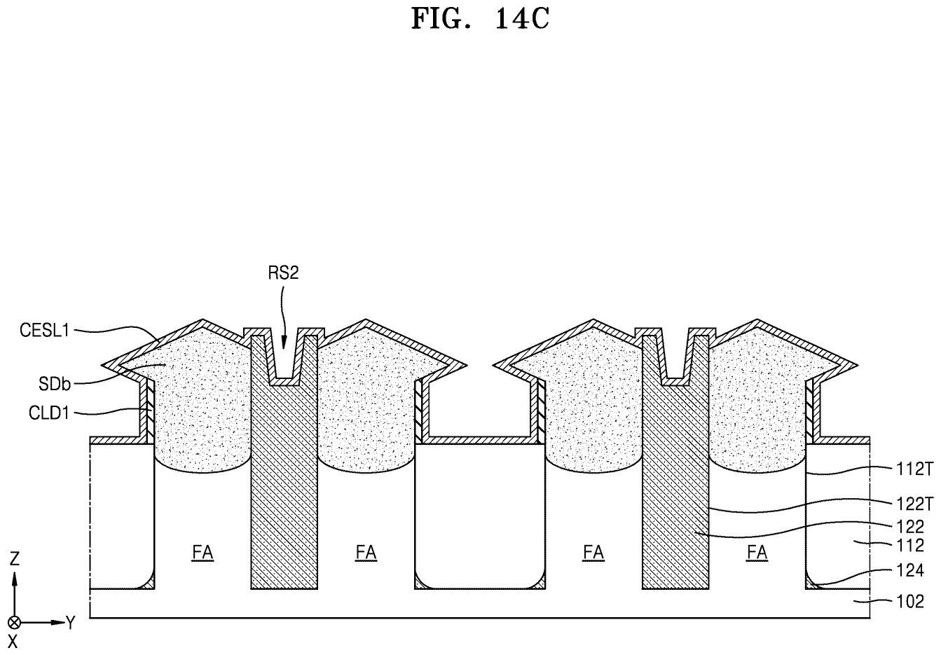

Referring to FIGS. 14A, 14B, and 14C, from the resultant product of FIGS. 13A and 13B, the first etching stop layer CESL1 covering at least a portion of the surface of the lower source/drain area SDb and the upper surface of the device separation layer 112 may be formed. The first etching stop layer CESL1 may cover the second recess RS2 formed in the nanosheet separation wall 122. The first etching stop layer CESL1 may include, for example, a silicon nitride layer.

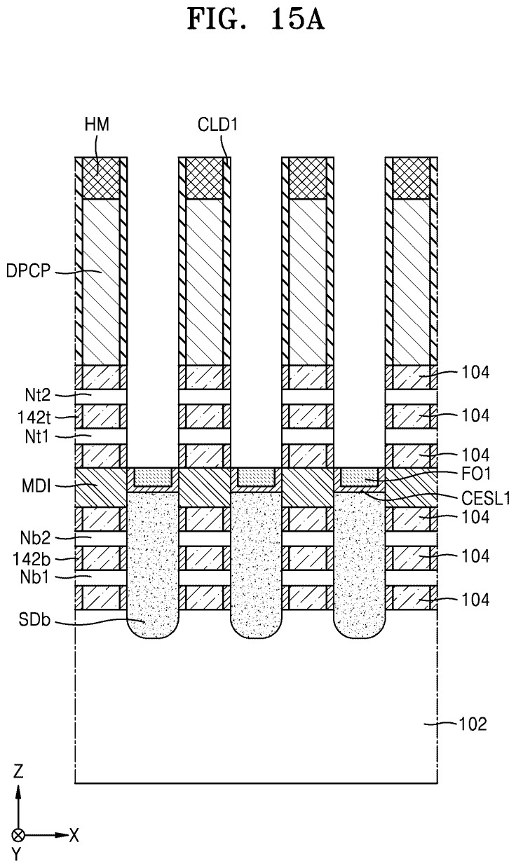

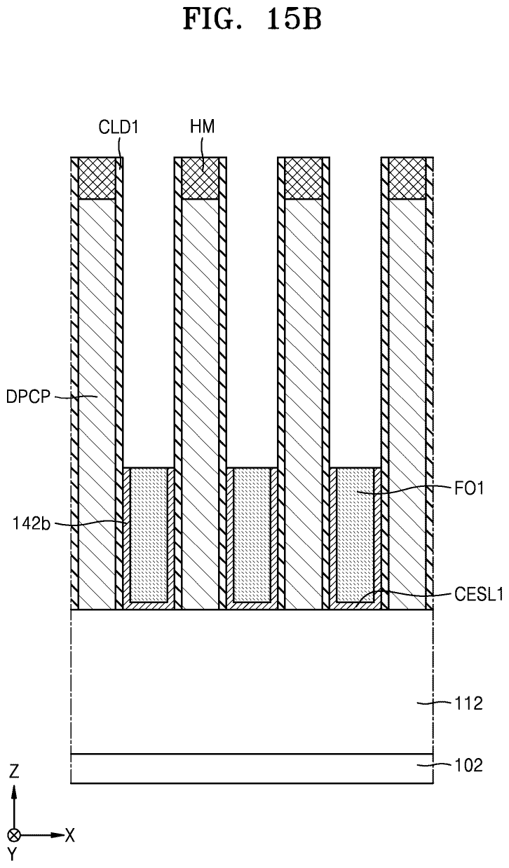

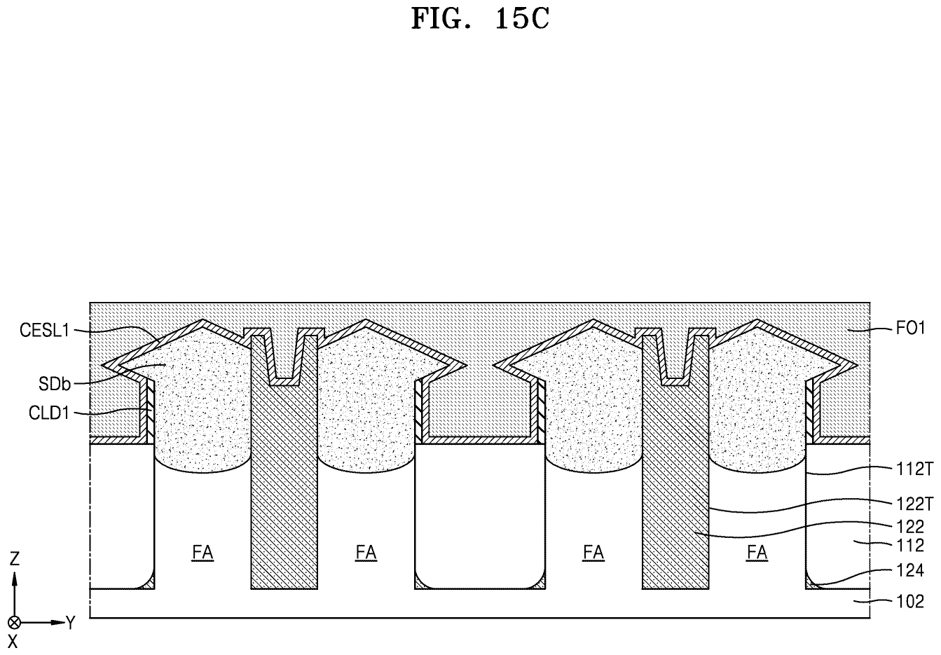

Referring to FIGS. 15A, 15B, and 15C, from the results of FIGS. 14A, 14B, and 14C, a first interlayer insulating layer FO1 covering the first etching stop layer CESL1 may be formed. Next, after a portion of the first interlayer insulating layer FO1 is removed, the upper surface of the first interlayer insulating layer FO1 may be at substantially the same vertical level as the upper surface of the intermediate insulating layer MDI. The first interlayer insulating layer FO1 may include, for example, silicon oxide.

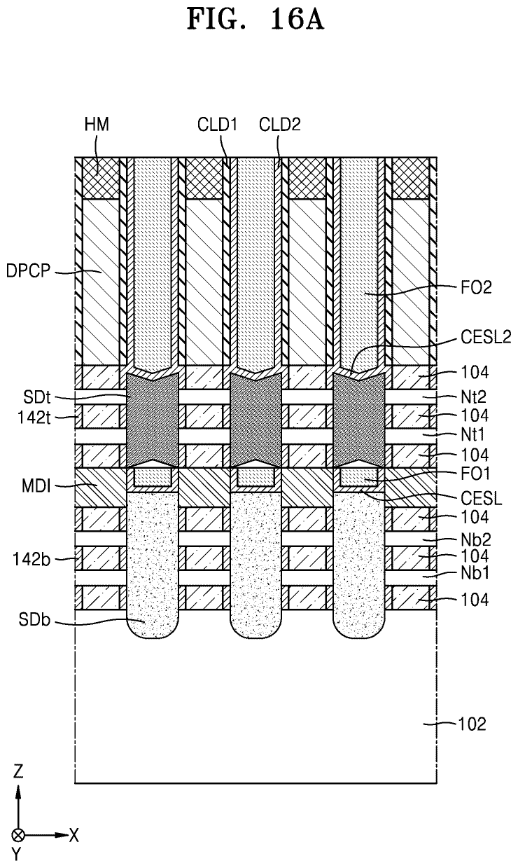

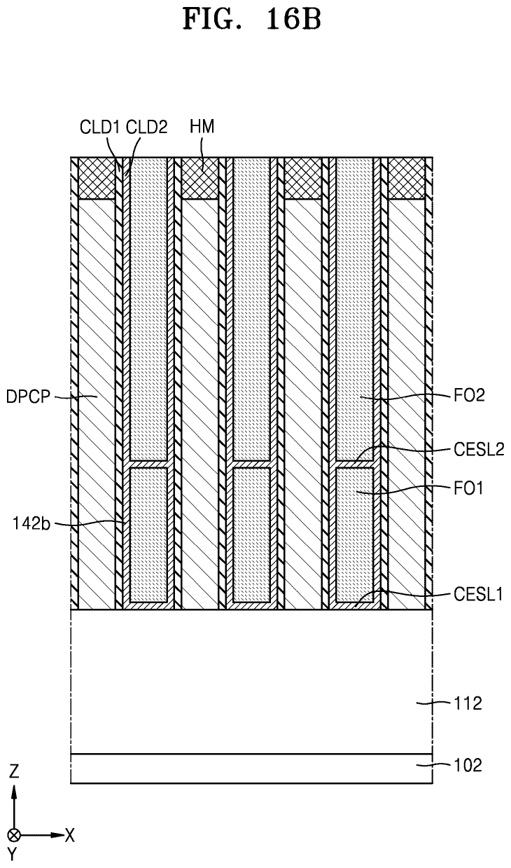

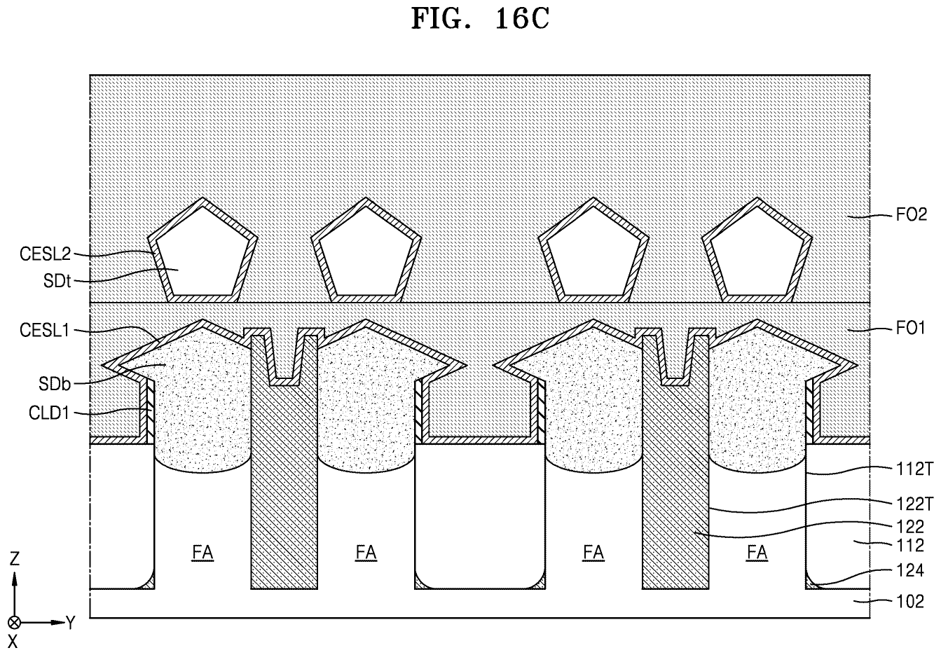

Referring to FIGS. 16A, 16B, and 16C, from the resultant product of FIGS. 15A, 15B, and 15C, an upper source/drain area SDt may be formed by using an epitaxial growth from both side surfaces of each of the third nanosheet Nt1 and the fourth nanosheet Nt2. The upper source/drain area SDt may include, for example, an embedded SiGe structure including a plurality of epitaxially grown SiGe layers, an epitaxially grown Si layer, or an epitaxially grown SiC layer. Next, a second etching stop layer CESL2 covering the surface of the upper source/drain area SDt may be formed. The second etching stop layer CESL2 may include, for example, a silicon nitride layer. Next, the second interlayer insulating layer FO2 may be formed on the second etching stop layer CESL2. The second interlayer insulating layer FO2 may include, for example, silicon oxide.

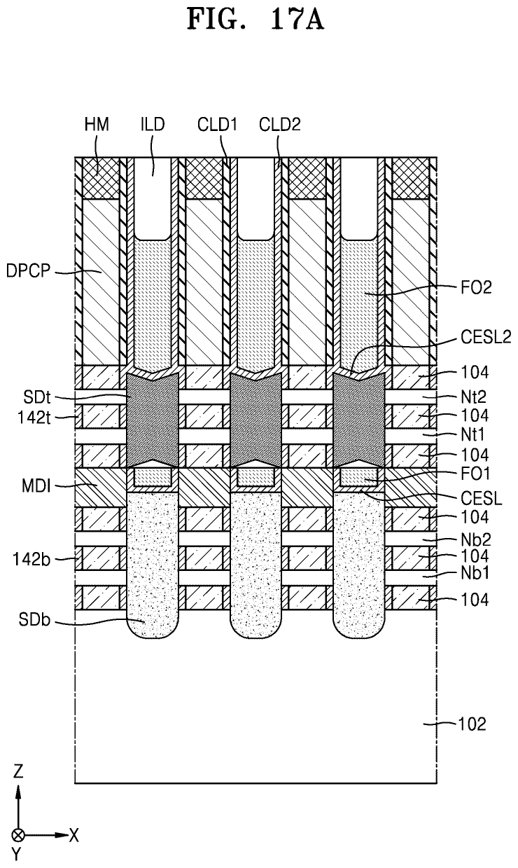

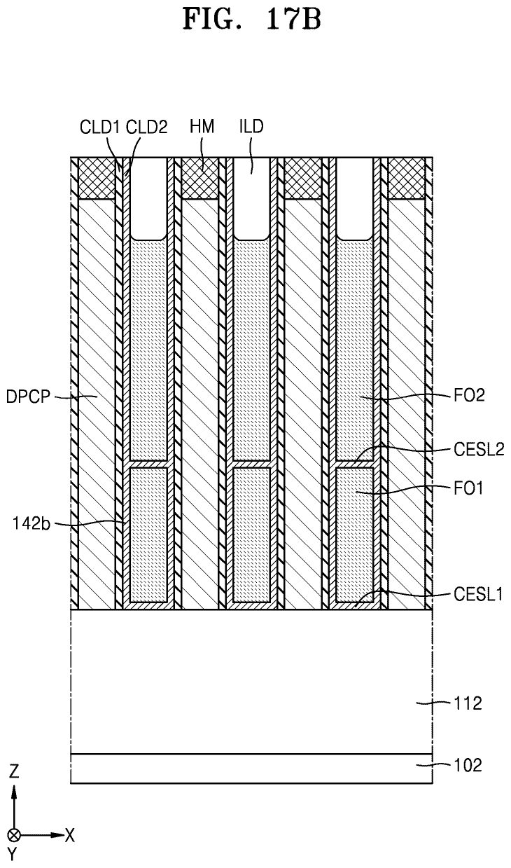

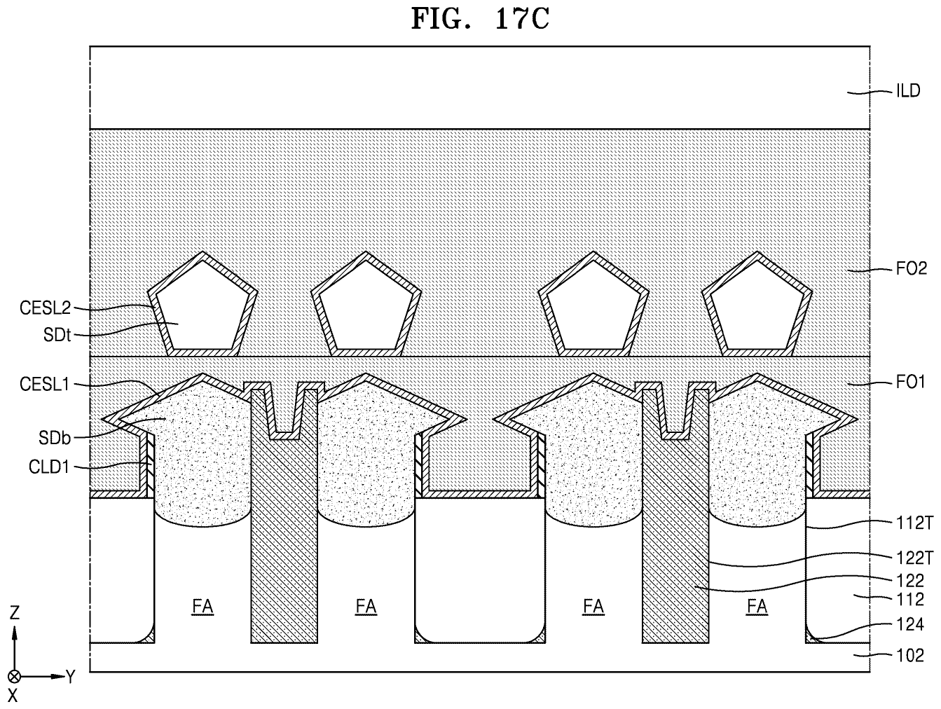

Referring to FIGS. 17A, 17B, and 17C, from the resultant product of FIGS. 16A, 16B, and 16C, a portion of the second interlayer insulating layer FO2 may be removed, and an upper insulating layer ILD filling a space, in which the portion of the second interlayer insulating layer FO2 has been removed, may be formed. The upper insulating layer ILD may cover an upper surface of the second interlayer insulating layer FO2. The upper insulating layer ILD may include, for example, silicon nitride.

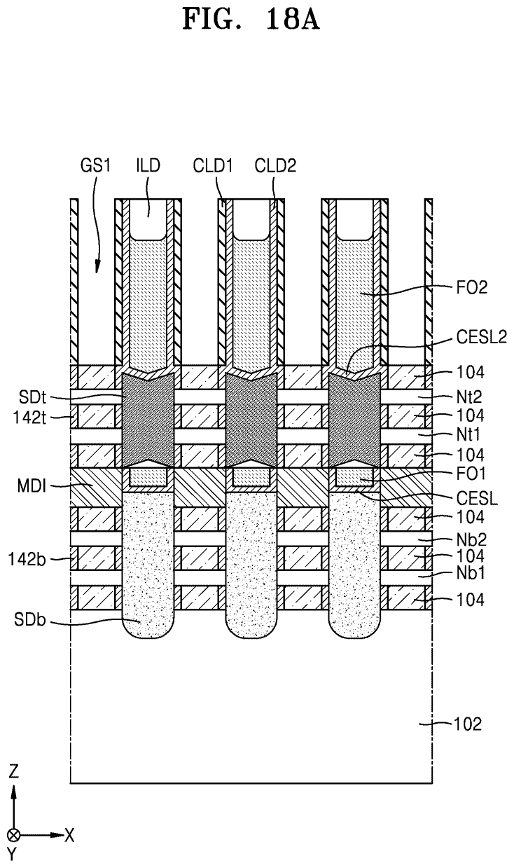

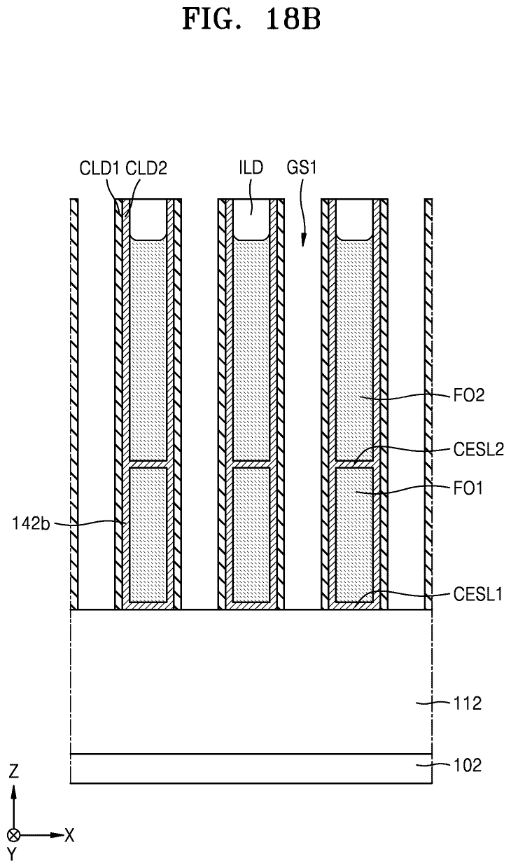

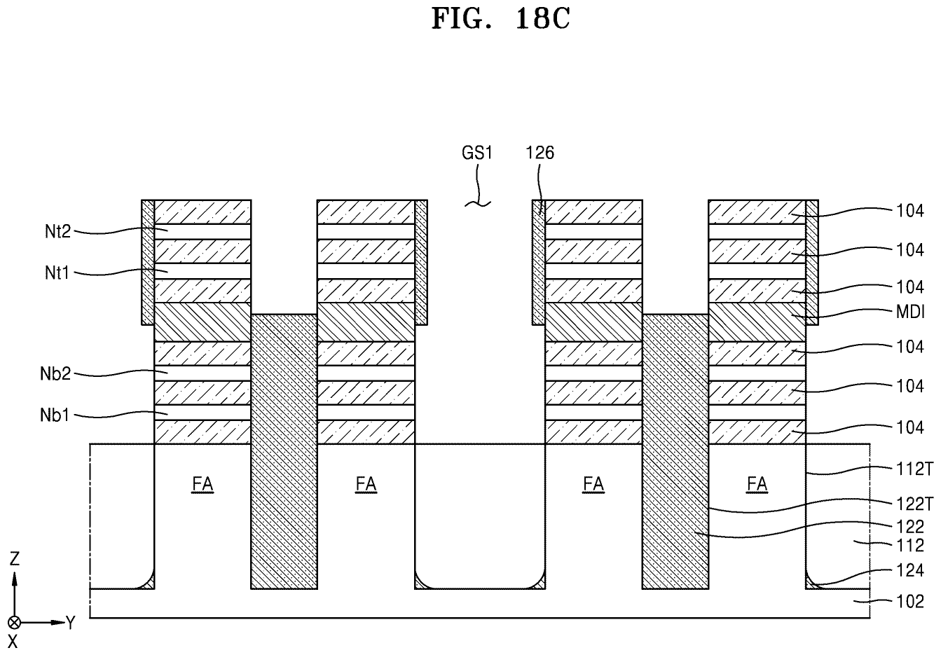

Referring to FIGS. 18A, 18B, and 18C, in the resultant product of FIGS. 17A, 17B, and 17C, a portion of the upper insulating layer ILD may be removed, and a patterned dummy gate electrode DPCP (refer to FIG. 17A) and the plurality of hard mask patterns HM (refer to FIG. 17A) may be removed to form a first gate space GS1. A portion of the upper insulating layer ILD may be removed by using, for example, a chemical mechanical polishing (CMP) process. The first gate space GS1 may expose at least a portion of an upper surface of the sacrificial layer 104 at the uppermost end among the plurality of sacrificial layers 104 and an upper surface of the device separation layer 112.

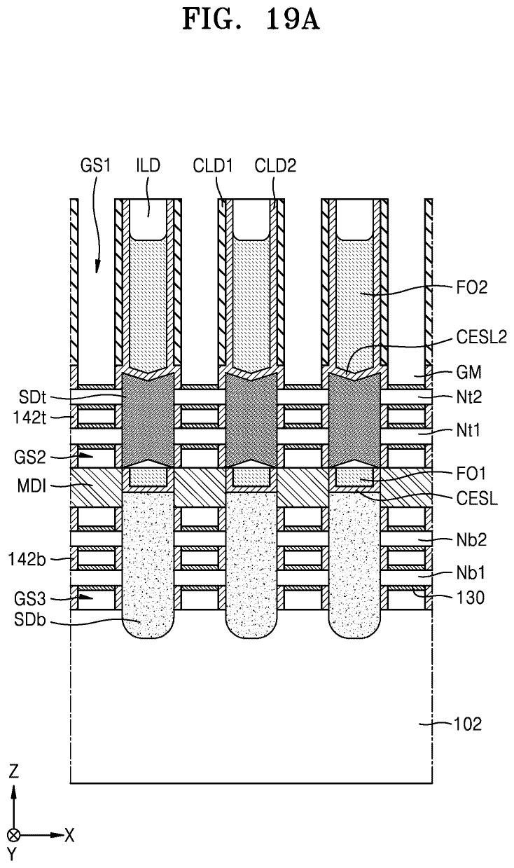

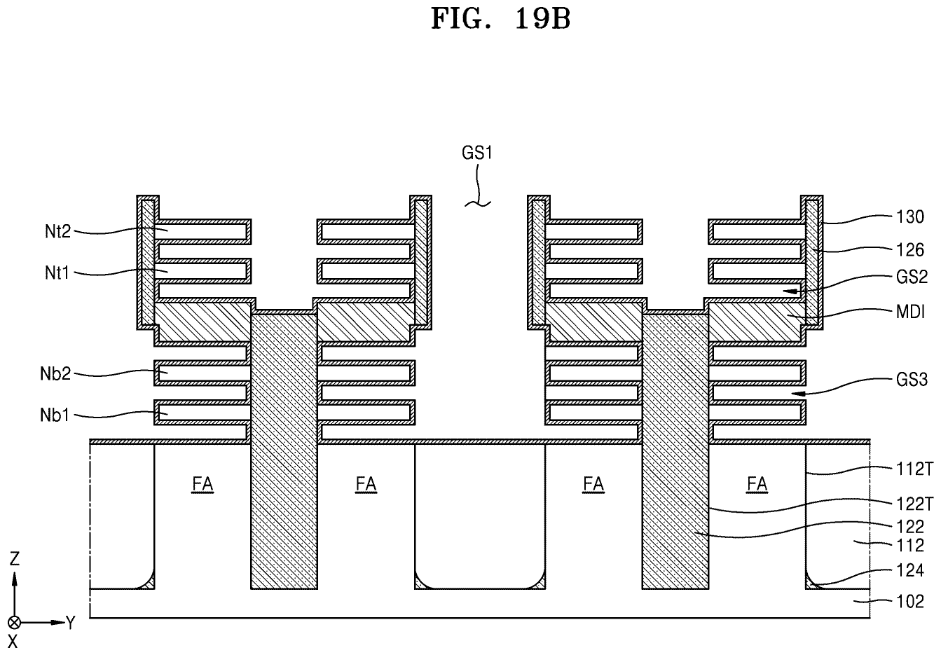

Referring to FIGS. 19A and 19B, from the resultant product of FIGS. 18A, 18B, and 18C, by removing the plurality of sacrificial layers 104 (refer to FIG. 18A) through the first gate space GS1, the second gate space GS2 and a third gate space GS3, the first gate space GS1, the second gate space GS2, and the third gate space GS3 may interconnected with each other. In some implementations, to selectively remove the plurality of sacrificial layers 104 (refer to FIG. 18A), an etching selectivity difference between the first nanosheet Nb1, the second nanosheet Nb2, the third nanosheet Nt1, and the fourth nanosheet Nt2, and the plurality of sacrificial layers 104 (refer to FIG. 18A) may be used. For example, a liquid or gaseous etchant may be used to selectively remove the plurality of sacrificial layers 104. In some implementations, to selectively remove the plurality of sacrificial layers 104, a CH₃COOH-based etchant, such as an etchant solution containing a mixture of CH₃COOH, HNO₃, and HF, or an etchant solution containing a mixture of CH₃COOH, H₂O₂, and HF, may be used, but is not limited thereto.

Next, the gate insulating layer 130 covering a surface of each of the first nanosheet Nb1, the second nanosheet Nb2, the third nanosheet Nt1, and the fourth nanosheet Nt2, which are exposed by the first gate space GS1, the second gate space GS2, and the third gate space GS3, may be formed.

In some implementations, after the process described with reference to FIGS. 19A and 19B is performed, a process of forming a dipole material layer covering at least a portion of the gate insulating layer 130 exposed by the second gate space GS2 and the third gate space GS3 is performed. For example, the dipole material layer may be formed on the gate insulating layer 130 covering at least one of a pair of lower nanosheet stacks NSSb or at least one of a pair of upper nanosheet stacks NSSt, which are spaced apart from each other with the nanosheet separation wall 122 therebetween.

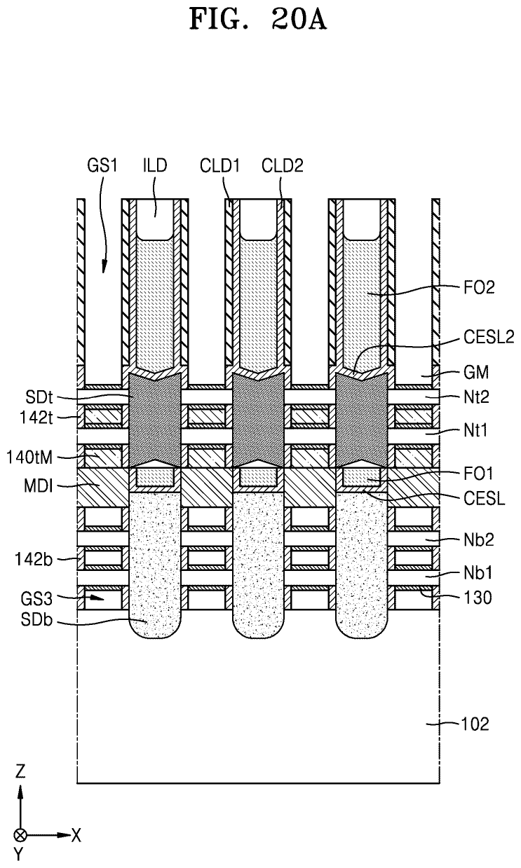

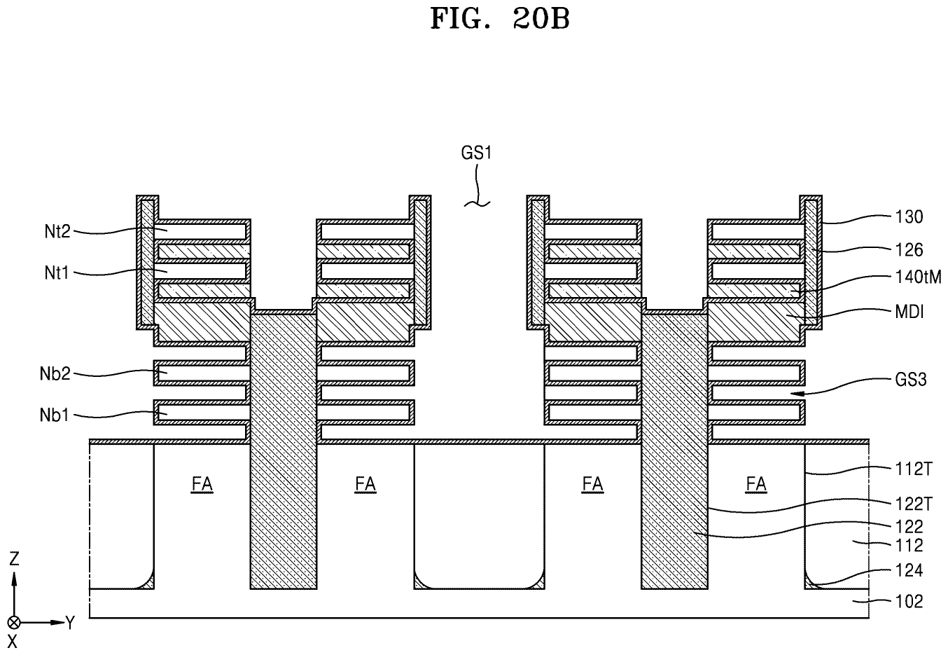

Referring to FIGS. 20A and 20B, from the resultant product of FIGS. 19A and 19B, a metal oxide layer 140tM filling the second gate space GS2 may be formed. The metal oxide layer 140tM may be formed by using, for example, a deposition process. The metal oxide layer 140tM may include, for example, aluminum oxide.

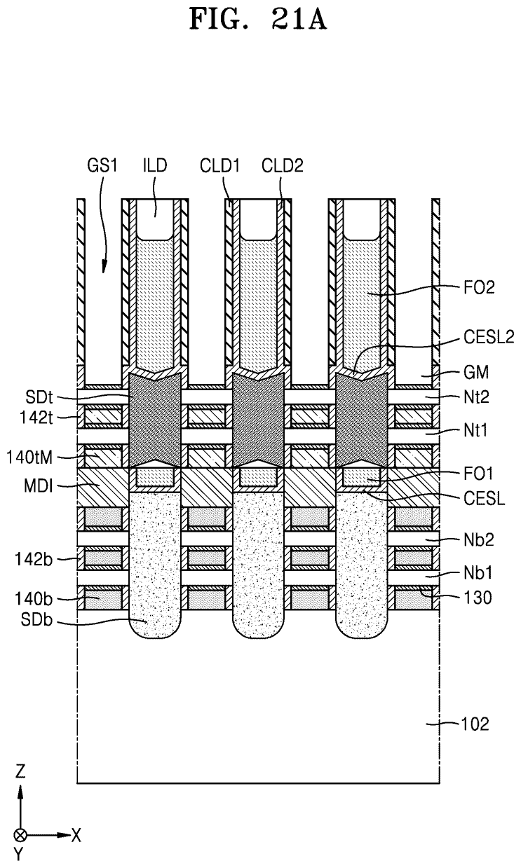

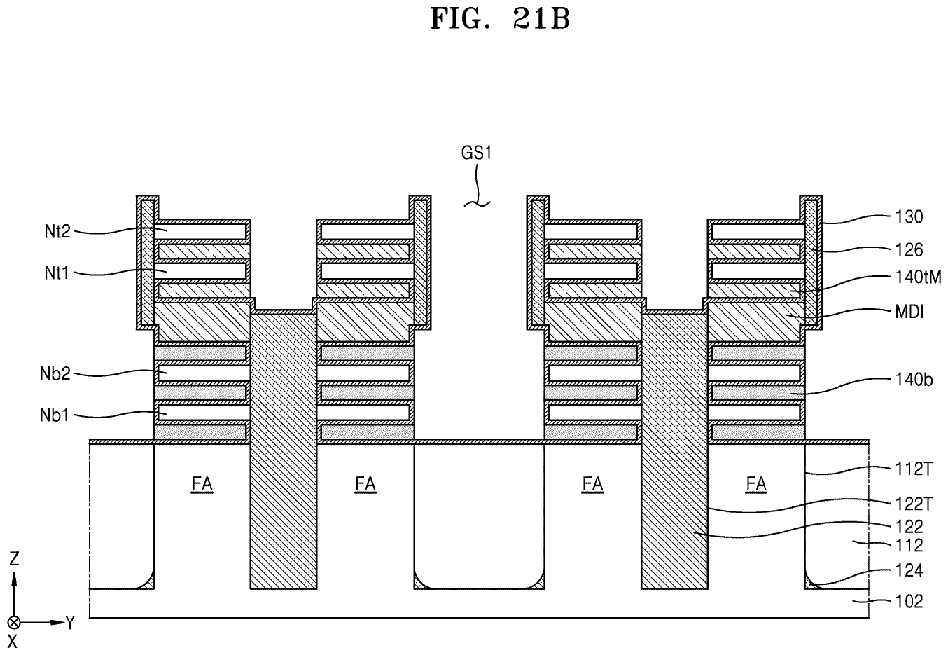

Referring to FIGS. 21A and 21B, from the resultant product of FIGS. 20A and 20B, the first metal layer 140b filling the third gate space GS3 (refer to FIG. 20A) may be formed. The first metal layer 140b may include, for example, a deposition process. A portion of the first metal layer 140b formed by using the deposition process beyond the third gate space GS3 may be removed by using the etch-back process, and only the first metal layer 140b filling the third gate space GS3 may remain. The first metal layer 140b may include, for example, a metal doped with a p-type dopant.

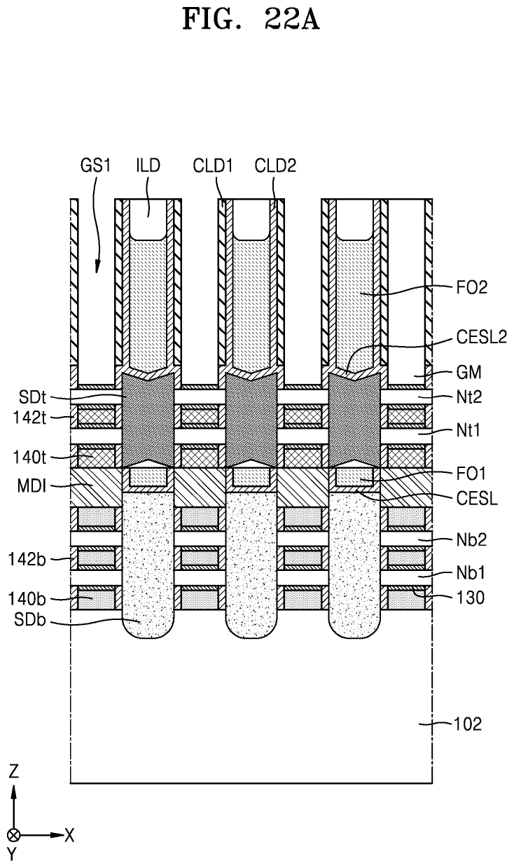

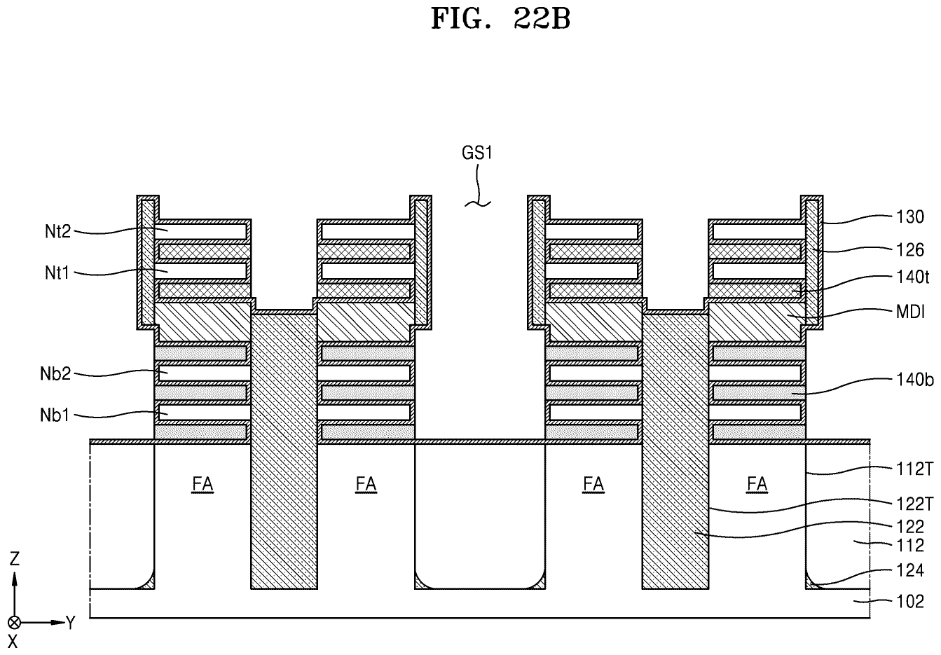

Referring to FIGS. 22A and 22B, from the resultant product of FIGS. 21A and 21B, the metal oxide layer 140tM (refer to FIG. 21A) filling the second gate space GS2 (refer to FIG. 19A) may be removed, and the second metal layer 140t filling the second gate space GS2 (refer to FIG. 21A), from which the metal oxide layer 140tM (refer to FIG. 21A) is removed, may be formed. The metal oxide layer 140tM (refer to FIG. 21A) may be removed by using, for example, a wet etching process. The second metal layer 140t may include, for example, a deposition process. A portion formed beyond the second gate space GS2 of the second metal layer 140t, which is formed by the deposition process, may be removed by using the etch-back process, and only the second metal layer 140t filling the second gate space GS2 may remain. The second metal layer 140t may include, for example, a metal doped with an n-type dopant.

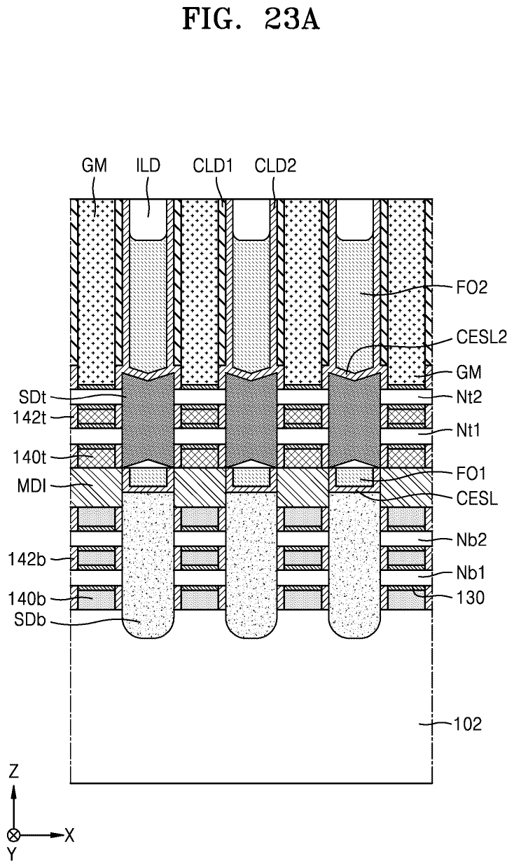

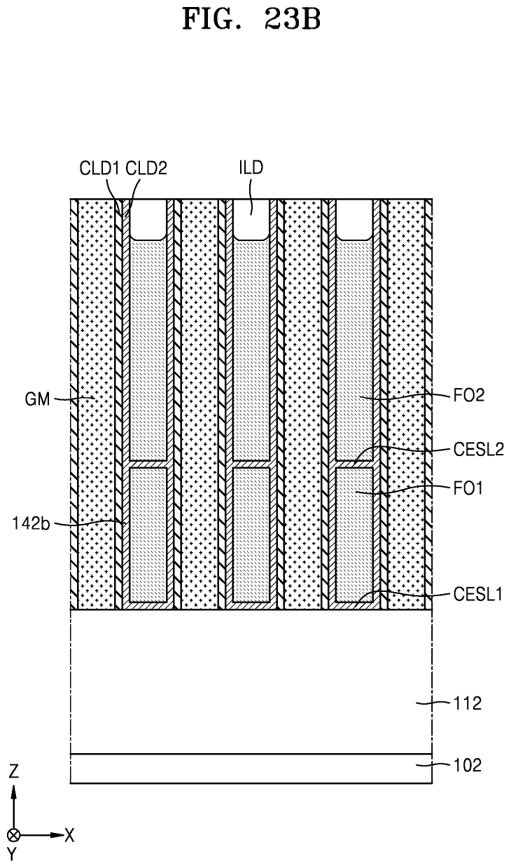

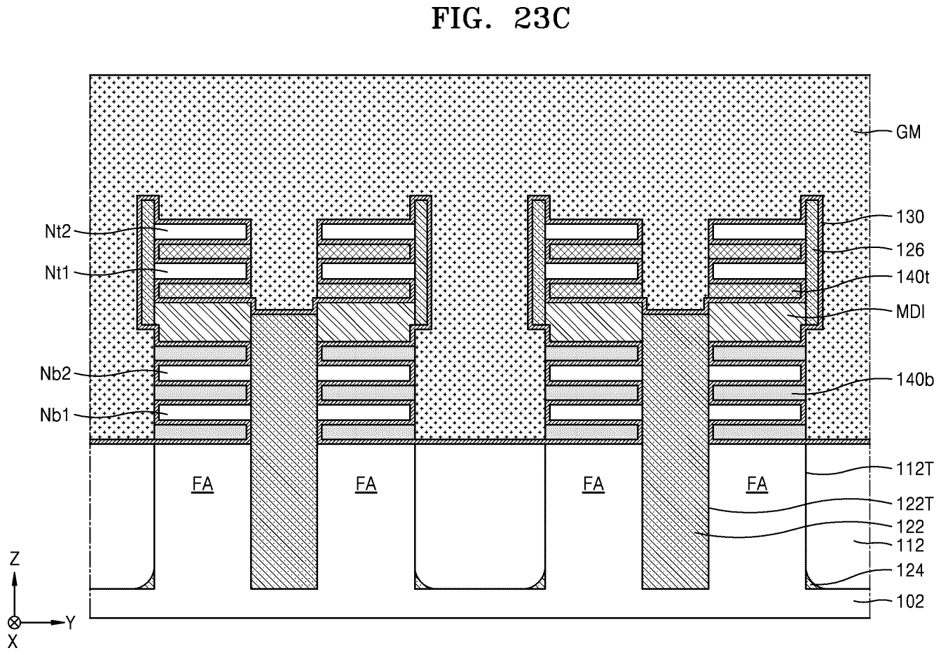

Referring to FIGS. 23A, 23B, and 23C, from the resultant product of FIGS. 22A and 22B, the third metal layer GM filling the first gate space GS1 (refer to FIG. 22A) may be formed. The third metal layer GM may be formed by using, for example, a deposition process. A third metal layer GM may include, for example, a metal, conductive metal nitride, conductive metal carbide, conductive metal silicide, or a combination thereof. The third metal layer GM formed as described above may include the upper gate metal layer GMt and the lower gate metal layer GMb, which are apart from each other by the gate separation spacer 126.

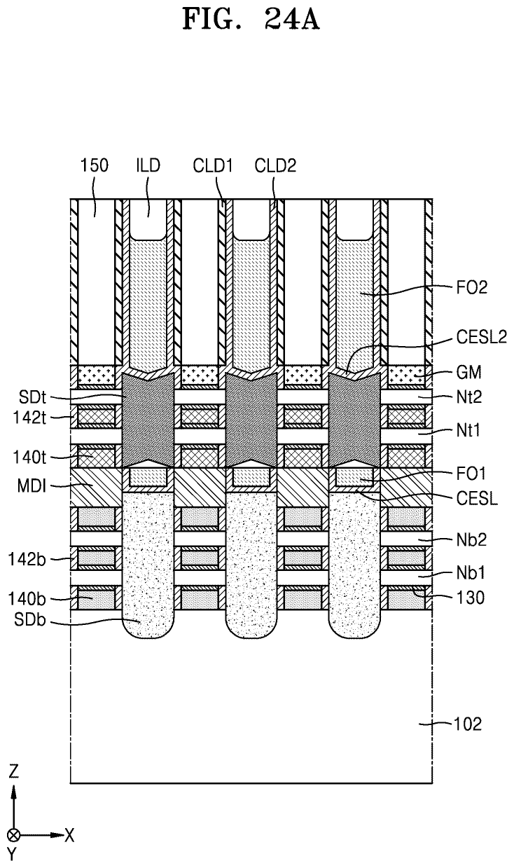

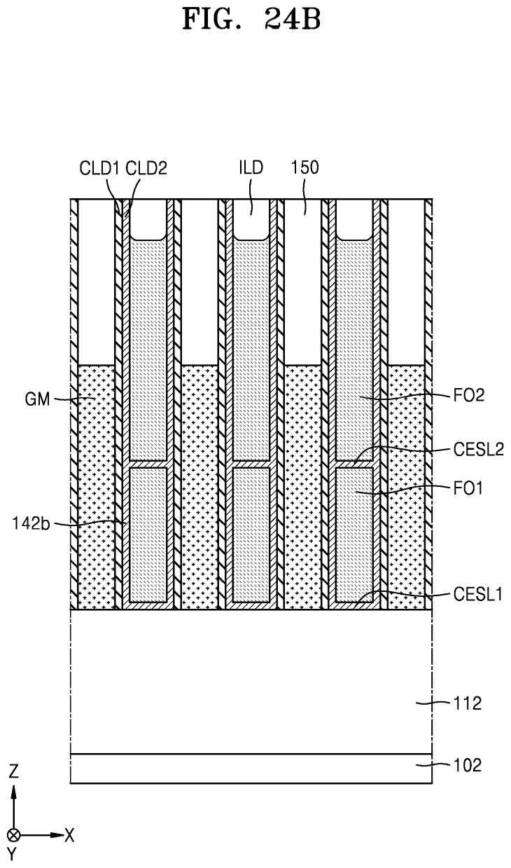

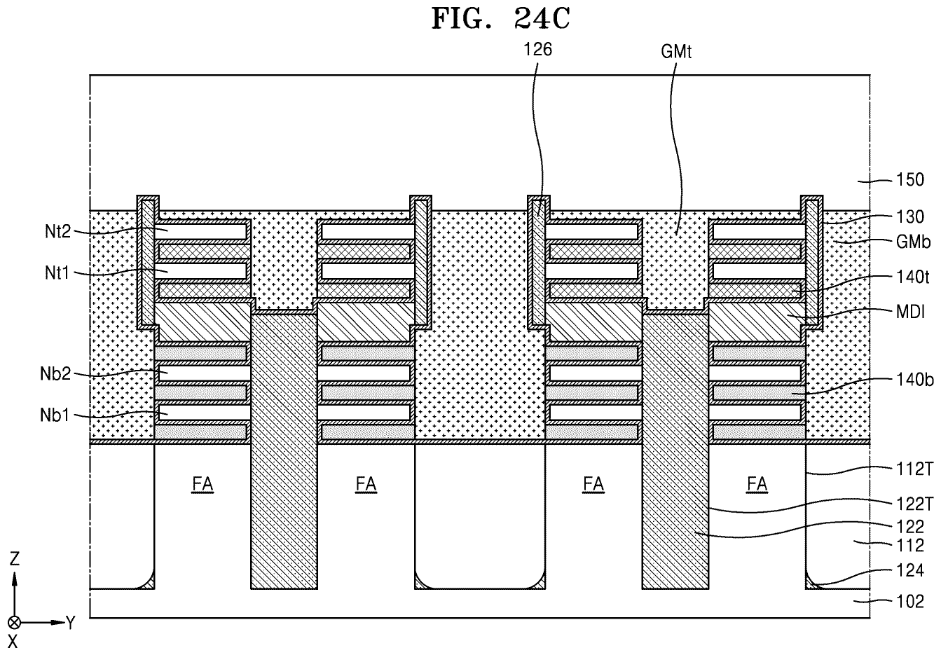

Referring to FIGS. 24A, 24B, and 24C, from the resultant product of FIGS. 23A, 23B, and 23C, a portion of the third metal layer GM may be removed, and then the gate capping layer 150 filling a space, from which the portion of the third metal layer GM has been removed, may be formed. The gate capping layer 150 may cover the upper surface of the third metal layer GM. The gate capping layer 150 may include, for example, silicon nitride.

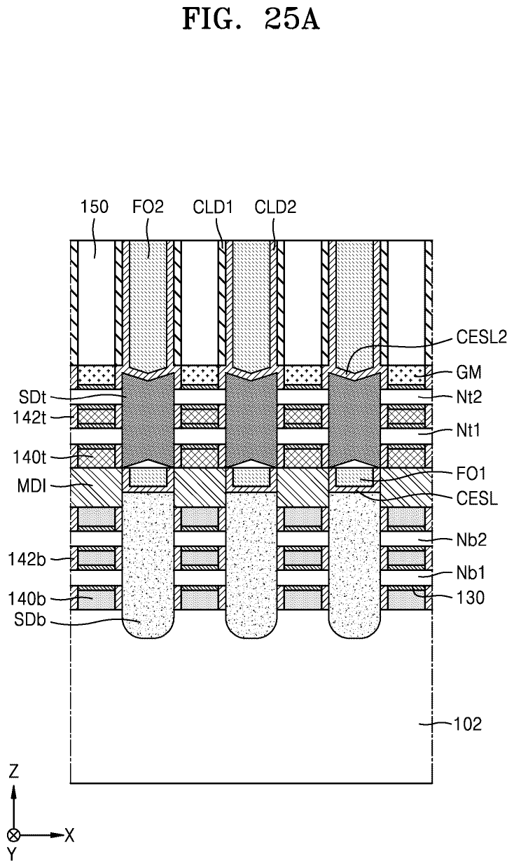

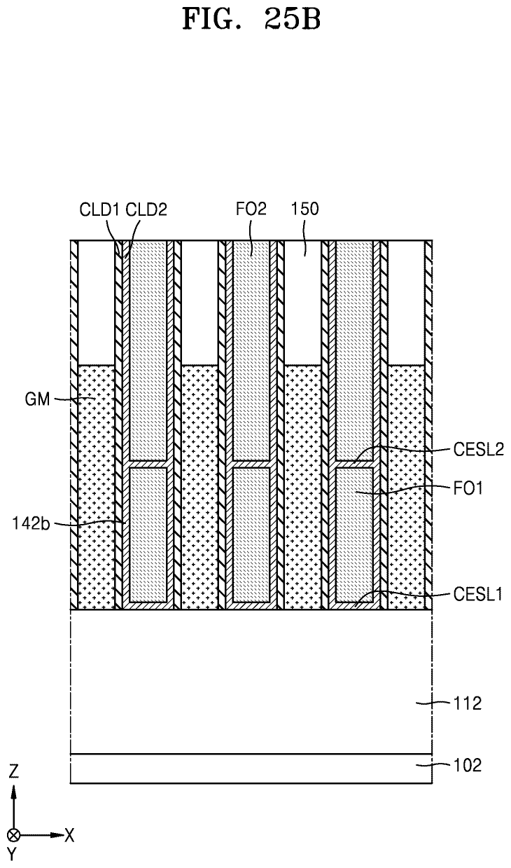

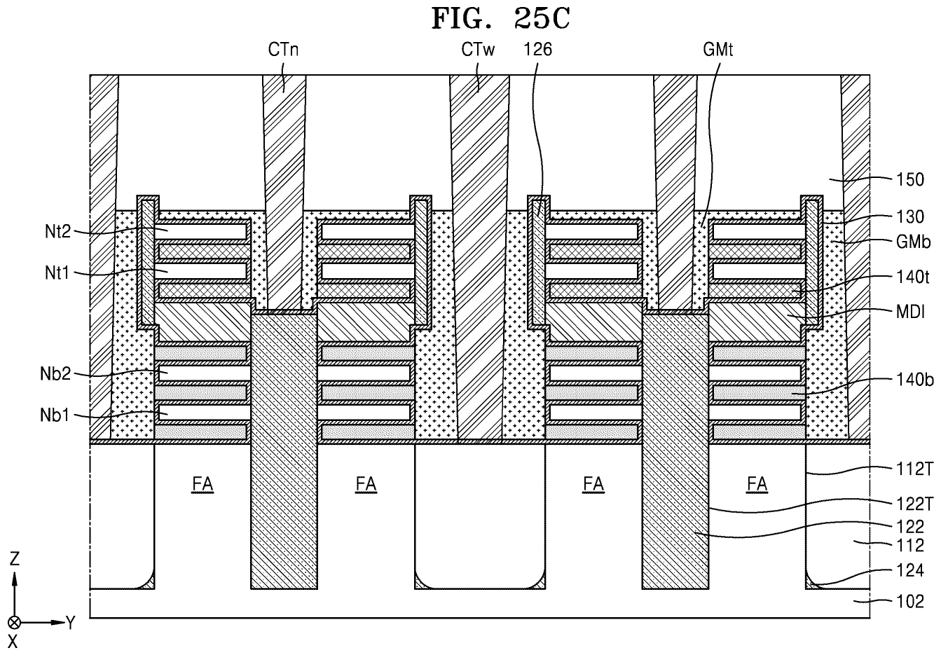

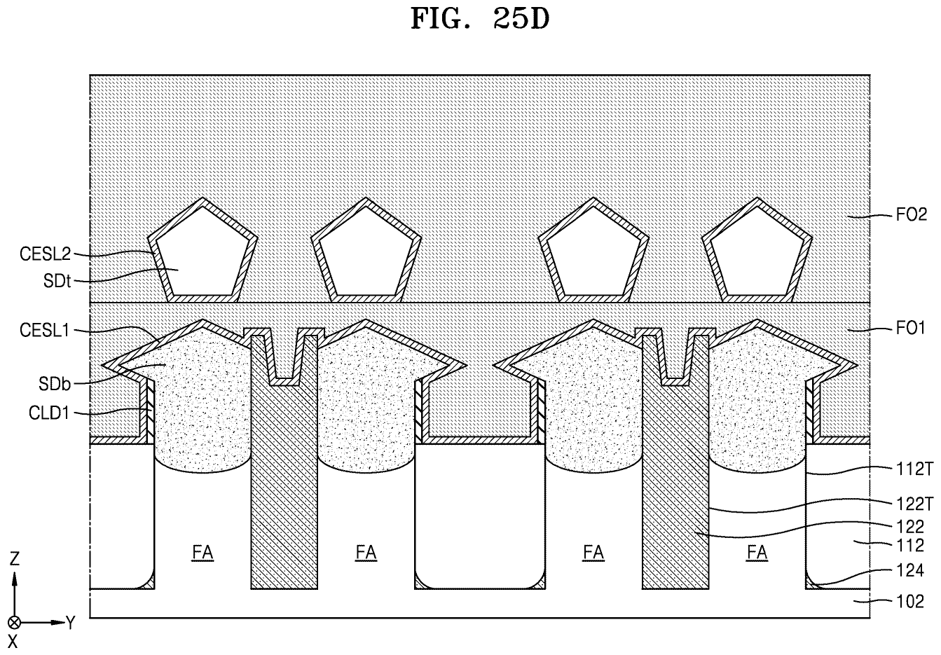

Referring to FIGS. 25A, 25B, 25C, and 25D, from the resultant product of FIGS. 24A, 24B, and 24C, the upper insulating layer ILD (refer to FIG. 24A), a portion of the gate capping layer 150, a portion of the first gate spacer CLD1, and a portion of the second gate spacer CLD2 may be removed. The upper insulating layer ILD (refer to FIG. 24A), a portion of the gate capping layer 150, a portion of the first gate spacer CLD1, and a portion of the second gate spacer CLD2 may be removed by using, for example, a chemical mechanical polishing (CMP) process. The upper insulating layer ILD (refer to FIG. 24A) may be completely removed by using the CMP process.

Next, the first gate cut structure CTn penetrating the gate capping layer 150 and the upper gate metal layer GMt and extending in the vertical direction (Z direction), and the second gate cut structure CTw penetrating the gate capping layer 150 and the lower gate metal layer GMb and extending in the vertical direction (Z direction) may be formed. The first gate cut structure CTn may be in contact with the upper surface of the nanosheet separation wall 122 on a bottom surface thereof, and the second gate cut structure CTw may be in contact with the upper surface of the device separation layer 112 on the bottom surface thereof.

In some implementations, after the processes described above with reference to FIGS. 25A, 25B, 25C, and 25D are performed, a process of forming the vertical via VV (refer to FIG. 3), which penetrates the second gate cut structure CTw and extends in the vertical direction (Z direction), is performed. In this case, processes described below with reference to FIGS. 26A, 26B, 26C, and 26D may be performed to manufacture the semiconductor device 100a illustrated in FIG. 3.

Referring to FIGS. 26A, 26B, 26C, and 26D, from the resultant product of FIGS. 25A, 25B, 25C, and 25D, a contact cut structure CX penetrating the second interlayer insulating layer FO2 and extending in the vertical direction (Z direction) may be formed. The contact cut structure CX may be in contact with the first interlayer insulating layer FO1 on a bottom surface thereof. Next, the first source/drain contact CAB penetrating the first interlayer insulating layer FO1 and the second interlayer insulating layer FO2 and extending in the vertical direction (Z direction), and the second source/drain contact CAt penetrating the second interlayer insulating layer FO2 and extending in the vertical direction (Z direction) may be formed. The first source/drain contact CAb may be in contact with the lower source/drain area SDb on a bottom surface thereof, and the second source/drain contact CAt may be in contact with the upper source/drain area SDt on the bottom surface thereof.

Next, from the resultant product of FIGS. 26A, 26B, 26C, and 26D, by forming the first gate contact CBb and the second gate contact CBt, which penetrate the gate capping layer 150 and extend in the vertical direction (Z direction), the semiconductor device 100 illustrated in FIGS. 1, 2a, and 2b may be manufactured.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been particularly shown and described, it will be understood that various change in form and details may be made therein without departing from the spirit and scope of the following claims.

What is claimed is:

1. A semiconductor device comprising:
a substrate including a pair of fin-type active areas and a device separation layer covering a sidewall of the pair of fin-type active areas;
a pair of nanosheet stacks arranged on the pair of fin-type active areas, respectively, wherein each nanosheet stack of the pair of nanosheet stacks includes a lower nanosheet stack arranged on a corresponding fin-type active area of the pair of fin-type active areas, and an upper nanosheet stack arranged on the lower nanosheet stack;
an intermediate insulating layer arranged between the lower nanosheet stack and the upper nanosheet stack of each of the pair of nanosheet stacks;
a nanosheet separation wall arranged between the pair of nanosheet stacks and extending in a first horizontal direction; and
a pair of gate lines on the pair of nanosheet stacks,
wherein the nanosheet separation wall separates the lower nanosheet stacks in the pair of nanosheet stacks from one another in a second horizontal direction.

2. The semiconductor device of claim 1,
wherein an upper surface of the nanosheet separation wall is at a lower vertical level than an upper surface of the intermediate insulating layer and at a higher vertical level than a lower surface of the intermediate insulating layer.

3. The semiconductor device of claim 1,
wherein the device separation layer is arranged in a device separation trench formed in the substrate, and wherein a residual insulating material is arranged on a lower end edge of a sidewall of the device separation trench adjacent to the pair of nanosheet stacks in the second horizontal direction.

4. The semiconductor device of claim 3, wherein the nanosheet separation wall and the residual insulating material comprise a same material.

5. The semiconductor device of claim 1, further comprising:
a first gate cut structure separating the upper nanosheet stacks in the pair of nano sheet stacks from one another in the second horizontal direction; and
a second gate cut structure separating another pair of nanosheet stacks, adjacent to the pair of nanosheet stacks, from the pair of nanosheet stacks in the second horizontal direction,
wherein a length of the first gate cut structure in the second horizontal direction is less than a length of the second gate cut structure in the second horizontal direction.

6. The semiconductor device of claim 5, wherein:
a bottom surface of the first gate cut structure is in contact with an upper surface of the nanosheet separation wall, and
a bottom surface of the second gate cut structure is in contact with the device separation layer.

7. The semiconductor device of claim 5, further comprising a vertical via extending vertically into the second gate cut structure.

8. The semiconductor device of claim 1, wherein the lower nanosheet stack and the upper nanosheet stack included in a first nanosheet stack of the pair of nanosheet stacks are connected to a gate contact.

9. A semiconductor device comprising:
a substrate including a pair of fin-type active areas and a device separation layer covering a sidewall of the pair of fin-type active areas;
a pair of nanosheet stacks arranged on the pair of fin-type active areas, respectively, wherein each nanosheet stack of the pair of nanosheet stacks includes a lower nanosheet stack arranged on a corresponding fin-type active area of the pair of fin-type active areas, and an upper nanosheet stack arranged on the lower nanosheet stack;
an intermediate insulating layer arranged between the lower nanosheet stack and the upper nanosheet stack of each of the pair of nanosheet stacks;
a nanosheet separation wall arranged between the pair of nanosheet stacks and extending in a first horizontal direction;
a gate separation spacer arranged on a first sidewall of a first nanosheet stack of the pair of nanosheet stacks, wherein the first sidewall is opposite a second sidewall of the first nanosheet stack, and wherein the second sidewall is closer to a second nanosheet stack of the pair of nanosheet stacks than is the first sidewall; and
a pair of gate lines on the pair of nanosheet stacks,
wherein the nanosheet separation wall separates the lower nanosheet stacks of the pair of nanosheet stacks from one another in a second horizontal direction.

10. The semiconductor device of claim 9, wherein an upper surface of the gate separation spacer is at a higher vertical level than an upper surface of the first nanosheet stack.

11. The semiconductor device of claim 9, wherein a lower surface of the gate separation spacer is at a lower vertical level than an upper surface of the intermediate insulating layer and at a higher vertical level than a lower surface of the intermediate insulating layer.

12. The semiconductor device of claim 9, wherein the gate separation spacer and the nanosheet separation wall comprise a same material.

13. The semiconductor device of claim 9,
wherein the lower nanosheet stack of the first nanosheet stack comprises a first nanosheet and a second nanosheet,
wherein the upper nanosheet stack of the first nanosheet stack comprises a third nanosheet and a fourth nanosheet,
wherein the pair of gate lines comprise:
a first metal layer arranged between the fin-type active area corresponding to the first nanosheet stack and the first nanosheet, between the first nanosheet and the second nanosheet, and between the second nanosheet and the intermediate insulating layer, and
a second metal layer and a third metal layer respectively arranged between the intermediate insulating layer and the third nanosheet and between the third nanosheet and the fourth nanosheet, and
wherein the third metal layer comprises a lower gate metal layer and an upper gate metal layer spaced apart from one another by the gate separation spacer.

14. The semiconductor device of claim 13, wherein
the lower nanosheet stack of the first nanosheet stack is electrically connected to a first gate contact in contact with the lower gate metal layer, and the upper nanosheet stack of the first nanosheet stack is electrically connected to a second gate contact in contact with the upper gate metal layer.

15. The semiconductor device of claim 9, wherein an upper surface of the nanosheet separation wall is at a lower vertical level than an upper surface of the intermediate insulating layer and at a higher vertical level than a lower surface of the intermediate insulating layer.

16. The semiconductor device of claim 9, wherein:
the device separation layer is arranged in a device separation trench formed in the substrate,
a residual insulating material is arranged on a lower end edge of a sidewalls of the device separation trench adjacent to the pair of nanosheet stacks in the second horizontal direction, and
the residual insulating material comprises a same material to that of the nanosheet separation wall.

17. The semiconductor device of claim 9, further comprising:
a first gate cut structure separating the upper nanosheet stacks of the pair of nano sheet stacks from one another in the second horizontal direction; and
a second gate cut structure separating another pair of nanosheet stacks, adjacent to the pair of nanosheet stacks, from the pair of nanosheet stacks in the second horizontal direction,
wherein a bottom surface of the first gate cut structure is in contact with an upper surface of the nanosheet separation wall,
wherein the second gate cut structure is in contact with the device separation layer, and
wherein a length of the first gate cut structure in the second horizontal direction is less than a length of the second gate cut structure in the second horizontal direction.

18. The semiconductor device of claim 17, comprising a vertical via configured to extending into the second gate cut structure and the device separation layer.

19. A semiconductor device comprising:
a substrate including a pair of fin-type active areas and a device separation layer covering a sidewall of the pair of fin-type active areas, wherein the device separation layer is arranged in a device separation trench;
a pair of nanosheet stacks arranged on the pair of fin-type active areas, respectively, wherein each nanosheet stack of the pair of nanosheet stacks includes a lower nanosheet stack arranged on a corresponding fin-type active area of the pair of fin-type active areas, and an upper nanosheet stack arranged on the lower nanosheet stack;
an intermediate insulating layer arranged between the lower nanosheet stack and the upper nanosheet stack of each of the pair of nanosheet stacks;
a nanosheet separation wall arranged between the pair of nanosheet stacks and extending in a first horizontal direction;
a residual insulating material arranged on a lower end edge of a sidewall of the device separation trench adjacent to the pair of nanosheet stacks in a second horizontal direction;
a gate separation spacer arranged on a first sidewall of a first nanosheet stack of the pair of nanosheet stacks, wherein the first sidewall is opposite a second sidewall of the first nanosheet stack, and wherein the second sidewall is closer to a second nanosheet stack of the pair of nanosheet stacks than is the first sidewall;
a pair of gate lines on the pair of nanosheet stacks, the pair of gate lines including a first metal layer, a second metal layer, and a third metal layer; and
a gate cut structure including:
a first gate cut structure separating the upper nanosheet stacks of the pair of nano sheet stacks from one another in the second horizontal direction, and
a second gate cut structure separating another pair of nanosheet stacks, adjacent to the pair of nanosheet stacks, from the pair of nanosheet stacks in the second horizontal direction,
wherein the nanosheet separation wall separates the lower nanosheet stacks of the pair of nanosheet stacks from one another in the second horizontal direction, and
wherein the third metal layer comprises a lower gate metal layer and an upper gate metal layer spaced apart from one another by the gate separation spacer.

20. The semiconductor device of claim 19, wherein the nanosheet separation wall, the gate separation spacer, and the residual insulating material comprise a same material comprising SiCN, SiBCN, or a combination thereof.
